(19) United States
(12) Patent Application Publication
(10) Pub. No.: US 2024/0310562 A1
(43) Pub. Date: Sep. 19, 2024

(54) CIRCULARLY POLARIZING PLATE, OPTICAL LAMINATE, ORGANIC ELECTROLUMINESCENT DISPLAY DEVICE, AND DISPLAY DEVICE

(71) Applicant: FUJIFILM Corporation, Tokyo (JP)

(72) Inventors: Yusuke FURUKI, Kanagawa (JP); Toshihiro KONISHI, Kanagawa (JP)

(73) Assignee: FUJIFILM Corporation, Tokyo (JP)

(21) Appl. No.: 18/652,412

(22) Filed: May 1, 2024

Related U.S. Application Data
(63) Continuation of application No. PCT/JP2022/041345, filed on Nov. 7, 2022.

(30) Foreign Application Priority Data
Nov. 8, 2021 (JP) 2021-182112

(51) Int. Cl. G02B 5/30

(52) U.S. Cl. CPC G02B 5/3016

(57) ABSTRACT

An optical laminate exhibits a change in tint when applied to a display device as a circularly polarizing plate in combination with a polarizer, and the display device is observed from an oblique direction at all azimuthal angles. A circularly polarizing plate, an organic electroluminescent display device, and a display device, each use the optical laminate. The circularly polarizing plate has a polarizer and an optical laminate which has, from the polarizer side, a first positive C-plate, a positive A-plate, and a λ/4 plate, an in-plane slow axis of the positive A-plate and an absorption axis of the polarizer are parallel to each other, an angle formed by the in-plane slow axis of the positive A-plate and an in-plane slow axis of the λ/4 plate is 45°±10°, and a difference in refractive index between the first positive C-plate and the positive A-plate is 0.08 or less.

### CROSS-REFERENCE TO RELATED APPLICATIONS

This application is a Continuation of PCT International Application No. PCT/JP2022/041345 filed on Nov. 7, 2022, which was published under PCT Article 21(2) in Japanese, and which claims priority under 35 U.S.C. § 119(a) to Japanese Patent Application No. 2021-182112 filed on Nov. 8, 2021. The above applications are hereby expressly incorporated by reference, in their entirety, into the present application.

### BACKGROUND OF THE INVENTION

### 1. Field of the Invention

The present invention relates to a circularly polarizing plate, an optical laminate, an organic electroluminescent display device, and a display device.

### 2. Description of the Related Art

An optical laminate having refractive index anisotropy is applied to various applications such as an antireflection film of a display device and an optical compensation film of a liquid crystal display device.

For example, JP5960743B discloses a phase difference plate in which two types of optically anisotropic layers exhibiting predetermined optical properties are laminated.

### SUMMARY OF THE INVENTION

The present inventors have found that, in a case where a phase difference plate on which an optically anisotropic layer is laminated, which is described in JP5960743B, is combined with a polarizer and then applied as a circularly polarizing plate to a display device, and the display device is observed from an oblique direction (a direction tilted from a normal direction of the display device) at all azimuthal angles, there is a large change in tint and therefore there is room for improvement.

The present invention has been made in view of the above-mentioned circumstances, and an object of the present invention is to provide an optical laminate that exhibits a small change in tint in a case where the optical laminate is applied to a display device as a circularly polarizing plate in combination with a polarizer, and the display device is observed from an oblique direction at all azimuthal angles.

Another object of the present invention is to provide a circularly polarizing plate, an organic electroluminescent display device, and a display device.

As a result of extensive studies on the problems of the related art, the present inventors have found that the foregoing objects can be achieved by the following configurations.
[1] A circularly polarizing plate including a polarizer; and an optical laminate,
in which the optical laminate has a first positive C-plate, a positive A-plate, and a λ/4 plate from a side of the polarizer,
an in-plane slow axis of the positive A-plate and an absorption axis of the polarizer are parallel to each other,
an angle formed by the in-plane slow axis of the positive A-plate and an in-plane slow axis of the λ/4 plate is 45°±10°,
in a case where the first positive C-plate and the positive A-plate are disposed adjacent to each other, a difference in refractive index between the first positive C-plate and the positive A-plate is 0.08 or less, and
in a case where another layer is disposed between the first positive C-plate and the positive A-plate, a larger difference in refractive index of a difference in refractive index between the first positive C-plate and the other layer and a difference in refractive index between the positive A-plate and the other layer is 0.08 or less.
[2] The circularly polarizing plate according to [1], in which a thickness direction retardation of the first positive C-plate at a wavelength of 550 nm is −65 to −45 nm.
[3] The circularly polarizing plate according to [1] or [2], in which an in-plane retardation of the positive A-plate at a wavelength of 550 nm is 65 to 85 nm.
[4] The circularly polarizing plate according to any one of [1] to [3], further including a second positive C-plate on a side of the λ/4 plate opposite to the side of the polarizer, in which a thickness direction retardation of the second positive C-plate at a wavelength of 550 nm is −45 to −35 nm.
[5] The circularly polarizing plate according to any one of [1] to [4], in which the λ/4 plate exhibits reverse wavelength dispersibility.
[6] The circularly polarizing plate according to any one of [1] to [5], in which the first positive C-plate and the positive A-plate are disposed adjacent to each other.
[7] The circularly polarizing plate according to [4], in which the λ/4 plate and the second positive C-plate are disposed adjacent to each other.
[8] The circularly polarizing plate according to any one of [1] to [7], in which any of the first positive C-plate, the positive A-plate, and the λ/4 plate is a layer formed of a liquid crystal compound.
[9] The circularly polarizing plate according to any one of [1] to [8], in which the polarizer is a polarizer formed of a composition containing a polymerizable liquid crystal compound.
[10] The circularly polarizing plate according to any one of [1] to [9], further including an adhesion layer in at least any of a space between the polarizer and the first positive C-plate, a space between the first positive C-plate and the positive A-plate, or a space between the positive A-plate and the λ/4 plate.
[11] The circularly polarizing plate according to [10], in which a difference in refractive index between the adhesion layer and an adjacent layer is 0.08 or less.
[12] An optical laminate including, in the following order: a first positive C-plate; a positive A-plate; and a λ/4 plate,
in which an angle formed by an in-plane slow axis of the positive A-plate and an in-plane slow axis of the λ/4 plate is 45°±10°,
in a case where the first positive C-plate and the positive A-plate are disposed adjacent to each other, a difference in refractive index between the first positive C-plate and the positive A-plate is 0.08 or less, and
in a case where another layer is disposed between the first positive C-plate and the positive A-plate, a larger difference in refractive index of a difference in refractive index between the first positive C-plate and the other layer and a difference in refractive index between the positive A-plate and the other layer is 0.08 or less.
[13] The optical laminate according to [12], in which a thickness direction retardation of the first positive C-plate at a wavelength of 550 nm is −65 to −45 nm.
[14] The optical laminate according to [12] or [13], in which an in-plane retardation of the positive A-plate at a wavelength of 550 nm is 65 to 85 nm.
[15] The optical laminate according to any one of [12] to [14], further including a second positive C-plate on a side of the λ/4 plate opposite to a side of the positive A-plate, in which a thickness direction retardation of the second positive C-plate at a wavelength of 550 nm is −45 to −35 nm.
[16] The optical laminate according to [12], in which the λ/4 plate exhibits reverse wavelength dispersibility.
[17] The optical laminate according to [12], in which the first positive C-plate and the positive A-plate are disposed adjacent to each other.
[18] The optical laminate according to [15], in which the λ/4 plate and the second positive C-plate are disposed adjacent to each other.
[19] The optical laminate according to [12], in which any of the first positive C-plate, the positive A-plate, and the λ/4 plate is a layer formed of a liquid crystal compound.
[20] The optical laminate according to [12], further including an adhesion layer in at least any of a space between the first positive C-plate and the positive A-plate or a space between the positive A-plate and the λ/4 plate.
[21] The optical laminate according to [20], in which a difference in refractive index between the adhesion layer and an adjacent layer is 0.08 or less.
[22] An organic electroluminescent display device including the circularly polarizing plate according to any one of [1] to [11] or the optical laminate according to any one of to [21].
[23] A display device including the circularly polarizing plate according to any one of [1] to [11] or the optical laminate according to any one of [12] to [21],
in which the circularly polarizing plate or the optical laminate is disposed along a curved surface of the display device.

In addition, according to an aspect of the present invention, it is possible to provide an optical laminate that exhibits a small change in tint in a case where the optical laminate is applied to a display device as a circularly polarizing plate in combination with a polarizer, and the display device is observed from an oblique direction at all azimuthal angles.

In addition, according to another aspect of the present invention, it is possible to provide a circularly polarizing plate, an organic electroluminescent display device, and a display device.

### BRIEF DESCRIPTION OF THE DRAWINGS

FIG. 1 is an example of a schematic cross-sectional view of an optical laminate of the present invention.

FIG. 2 is a view showing a relationship between an in-plane slow axis of a positive A-plate and an in-plane slow axis of a λ/4 plate in the optical laminate of the present invention.

FIG. 3 is an example of a schematic cross-sectional view of a circularly polarizing plate of the present invention.

FIG. 4 is a view showing a relationship among an absorption axis of a polarizer, an in-plane slow axis of a positive A-plate, and an in-plane slow axis of a λ/4 plate in the circularly polarizing plate of the present invention.

FIG. 5 is an example of a schematic cross-sectional view of an organic electroluminescent display device of the present invention.

### DESCRIPTION OF THE PREFERRED EMBODIMENTS

Hereinafter, the present invention will be described in more detail.

Any numerical range expressed using “to” in the present specification refers to a range including the numerical values before and after the “to” as a lower limit value and an upper limit value, respectively.

In addition, the in-plane slow axis and the in-plane fast axis are defined at a wavelength of 550 nm unless otherwise specified. That is, unless otherwise specified, for example, an in-plane slow axis direction means a direction of an in-plane slow axis at a wavelength of 550 nm.

In the present invention, Re(λ) and Rth(λ) represent an in-plane retardation at a wavelength of λ and a thickness direction retardation at a wavelength of λ, respectively. Unless otherwise specified, the wavelength of λ is 550 nm.

In the present invention, Re(λ) and Rth(λ) are values measured at a wavelength of λ in AxoScan OPMF-1 (manufactured by Opto Science, Inc.). By inputting an average refractive index ((nx+ny+nz)/3) and a film thickness (d (μm)) to AxoScan, the values can be calculated:
slow axis direction (°)

$$\begin{matrix}Re ( λ ) = R 0 ( λ ) \\ Rth ( λ ) = ( ( n x + ny ) / 2 - nz ) \times d\end{matrix}$$

Note that R0(λ) is displayed as a numerical value calculated by AxoScan OPMF-1, and means Re(λ).

In the present specification, the refractive indices nx, ny, and nz are measured using an Abbe refractometer (NAR-4T, manufactured by Atago Co., Ltd.) and using a sodium lamp (λ=589 nm) as a light source. In addition, in a case where a wavelength dependence is measured, the wavelength dependence can be measured with a multi-wavelength Abbe refractometer DR-M2 (manufactured by Atago Co., Ltd.) in combination with a dichroic filter.

In addition, values from Polymer Handbook (JOHN WILEY & SONS, INC.) and catalogs of various optical films can be used. Examples of average refractive index values for major optical films are given below: cellulose acylate (1.48), cycloolefin polymer (1.52), polycarbonate (1.59), polymethyl methacrylate (1.49), and polystyrene (1.59).

In the present specification, the A-plate and the C-plate are defined as follows.

There are two types of A-plates, that is, a positive A-plate (A-plate which is positive) and a negative A-plate (A-plate which is negative). The positive A-plate satisfies a relationship of Expression (A1) and the negative A-plate satisfies a relationship of Expression (A2) in a case where a refractive index in an in-plane slow axis direction of a film (in a direction in which an in-plane refractive index is maximum) is defined as nx, a refractive index in an in-plane direction orthogonal to the in-plane slow axis is defined as ny, and a refractive index in a thickness direction is defined as nz. Note that the positive A-plate has an Rth showing a positive value and the negative A-plate has an Rth showing a negative value.

$$n x > ny \approx nz \qquad Expression ( A1 )$$

$$ny < nx \approx nz \qquad Expression ( A2 )$$

Note that the symbol “≈” encompasses not only a case where the both sides are completely the same as each other but also a case where the both sides are substantially the same as each other. The phrase “substantially the same as each other” means that, for example, a case where (ny−nz)×d (where d is a thickness of a film) is −10 to 10 nm and preferably −5 to 5 nm is also included in “ny≈nz”; and a case where (nx−nz)×d is −10 to 10 nm and preferably −5 to 5 nm is also included in “nx≈nz”.

There are two types of C-plates, that is, a positive C-plate (C-plate which is positive) and a negative C-plate (C-plate which is negative). The positive C-plate satisfies a relationship of Expression (C1) and the negative C-plate satisfies a relationship of Expression (C2). Note that the positive C-plate has an Rth showing a negative value and the negative C-plate has an Rth showing a positive value.

$$nz > nx \approx ny \qquad Expression ( C1 )$$

$$nz < nx \approx ny \qquad Expression ( C2 )$$

Note that the symbol “≈” encompasses not only a case where the both sides are completely the same as each other but also a case where the both sides are substantially the same as each other. The phrase “substantially the same as each other” means that, for example, a case where (nx−ny)×d (where d is a thickness of a film) is 0 to 10 nm and preferably 0 to 5 nm is also included in “nx≈ny”.

In the present specification, the “visible light” is intended to refer to light having a wavelength of 400 to 700 nm. In addition, the “ultraviolet ray” is intended to refer to light having a wavelength of 10 nm or longer and shorter than 400 nm.

In addition, in the present specification, the term “orthogonal” is intended to include a range of errors acceptable in the art to which the present invention pertains. For example, it means that an angle is in an error range of ±5° with respect to an exact angle, and the error with respect to the exact angle is preferably in a range of ±3°.

In addition, in the present specification, the term “parallel” is intended to include a range of errors acceptable in the art to which the present invention pertains. For example, it means that an angle is in a range of an exact angle ±20°, and the error with respect to the exact angle is preferably in a range of ±10°, more preferably in a range of ±5°, and still more preferably in a range of ±3°.

A feature point of the optical laminate according to the embodiment of the present invention is that predetermined optically anisotropic layers are used in combination.

More specifically, the optical laminate according to the embodiment of the present invention is an optical laminate having a first positive C-plate, a positive A-plate, and a λ/4 plate in this order, in which an angle formed by an in-plane slow axis of the positive A-plate and an in-plane slow axis of the λ/4 plate is 45°±10°, in a case where the first positive C-plate and the positive A-plate are disposed adjacent to each other, a difference in refractive index between the first positive C-plate and the positive A-plate is 0.08 or less, and in a case where another layer is disposed between the first positive C-plate and the positive A-plate, a larger difference in refractive index of a difference in refractive index between the first positive C-plate and the other layer and a difference in refractive index between the positive A-plate and the other layer is 0.08 or less.

Although the mechanism is not necessarily clear by which, with the above-mentioned configuration, the optical laminate according to the embodiment of the present invention exhibits a small change in tint in a case where the optical laminate is applied to a display device as a circularly polarizing plate in combination with a polarizer, and the display device is observed from an oblique direction at all azimuthal angles, the present inventors speculate as follows.

With regard to a circularly polarizing plate having normal polarizer and λ/4 plate, in a case where a display device is observed from an oblique direction (a direction tilted from a normal direction of the display device), an azimuth relationship between the absorption axis of the polarizer and the λ/4 plate may change from the azimuth relationship in a front direction of the display device (normal direction of the display device). In a case where the azimuth relationship changes as described above, a change in tint may occur in a case where the display device is observed from an oblique direction at all azimuthal angles. In the optical laminate according to the embodiment of the present invention, it is thought that inclusion of the first positive C-plate, the positive A-plate, and the λ/4 plate in this order makes it possible to optically compensate for the change in the azimuth relationship as described above, and as a result, a change in tint is small in a case where the display device is observed from an oblique direction at all azimuthal angles. In addition, it is thought that since the difference in refractive index mentioned above is equal to or less than a predetermined value, reflection at an interface is less likely to occur, so a change in tint is further reduced in a case where the display device is observed from an oblique direction at all azimuthal angles.

### <Optical Laminate>

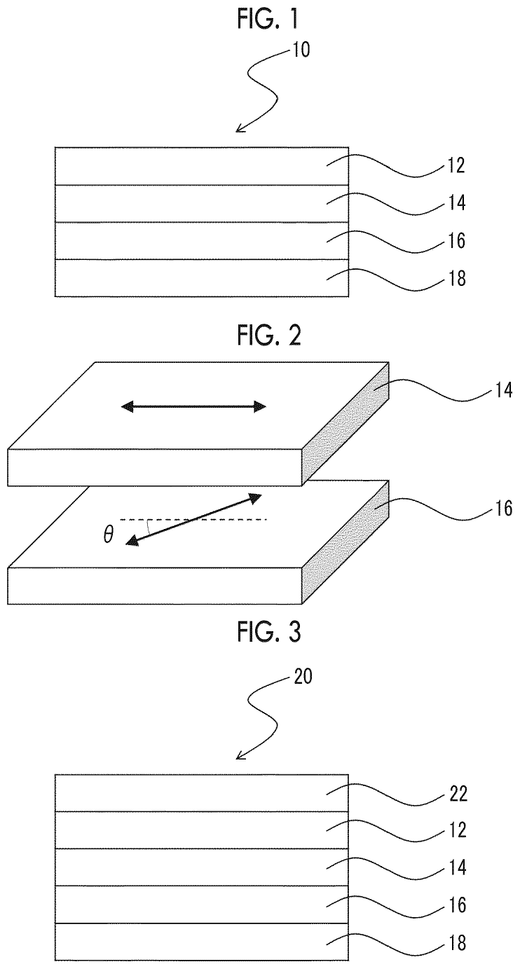

Hereinafter, the optical laminate according to the embodiment of the present invention will be described with reference to the accompanying drawings. FIG. 1 shows a schematic cross-sectional view of the optical laminate according to the embodiment of the present invention.

An optical laminate 10 according to the embodiment of the present invention has a first positive C-plate 12, a positive A-plate 14, and a λ/4 plate 16 in this order. The optical laminate 10 may further have a second positive C-plate 18 as shown in FIG. 1. In this case, it is preferable that the optical laminate 10 has the first positive C-plate 12, the positive A-plate 14, the λ/4 plate 16, and the second positive C-plate 18 in this order. That is, it is preferable that the optical laminate 10 according to the embodiment of the present invention has the second positive C-plate 18 on the side of the λ/4 plate 16 opposite to the side of the positive A-plate 14. Note that the optical laminate 10 according to the embodiment of the present invention may not have the second positive C-plate 18.

In addition, FIG. 2 shows a relationship between the in-plane slow axis of the positive A-plate 14 and the in-plane slow axis of the λ/4 plate 16. In FIG. 2, arrows in the positive A-plate 14 and the λ/4 plate 16 indicate the direction of the in-plane slow axis in each layer. In FIG. 2, an angle θ formed by the in-plane slow axis of the positive A-plate 14 and the in-plane slow axis of the λ/4 plate 16 is 45±10°.

Hereinafter, each member included in the optical laminate 10 will be described in detail.

### (First Positive C-Plate)

The first positive C-plate is an optically anisotropic layer disposed closest to the polarizer in a circularly polarizing plate which will be described later.

The Rth(550) which is a thickness direction retardation of the first positive C-plate at a wavelength of 550 nm is not particularly limited, and is preferably −75 to −35 nm and more preferably −65 to −45 nm from the viewpoint that there is a smaller change in tint (hereinafter, also simply referred to as “the effect of the present invention is more excellent”) in a case where the optical laminate according to the embodiment of the present invention is combined with a polarizer and then applied as a circularly polarizing plate to a display device, and the display device is observed from an oblique direction at all azimuthal angles.

The configuration of the first positive C-plate is not particularly limited, and examples thereof include a layer formed by fixing a rod-like liquid crystal compound vertically aligned and a resin film, among which a layer formed by fixing a rod-like liquid crystal compound vertically aligned is preferable from the viewpoint that the effect of the present invention is more excellent.

Note that the state in which a rod-like liquid crystal compound is vertically aligned means that a major axis of the rod-like liquid crystal compound and a thickness direction of the first positive C-plate are parallel to each other. It is not required to be strictly parallel, and the angle formed by the major axis of the rod-like liquid crystal compound and the thickness direction of the first positive C-plate is preferably in a range of 0°±20° and more preferably in a range of 0°±10°.

Note that in the present specification, a “fixed” state is a state in which alignment of a liquid crystal compound is maintained. Specifically, the “fixed” state is preferably a state in which a layer has no fluidity in a temperature range of 0° C. to 50° C. in general or −30° C. to 70° C. under more severe conditions, and a fixed alignment morphology can be stably maintained without causing any change in the alignment morphology due to an external field or an external force.

A known compound can be used as the rod-like liquid crystal compound.

Examples of the rod-like liquid crystal compound include the compounds described in claim 1 of JP1999-513019A (JP-H11-513019A) and paragraphs to of JP2005-289980A.

The rod-like liquid crystal compound may have a polymerizable group.

In the present specification, the type of the polymerizable group is not particularly limited, and is preferably a functional group capable of an addition polymerization reaction, more preferably a polymerizable ethylenically unsaturated group or a ring-polymerizable group, and still more preferably a (meth)acryloyl group, a vinyl group, a styryl group, or an allyl group.

The first positive C-plate is preferably a layer formed by fixing a rod-like liquid crystal compound vertically aligned and having a polymerizable group by polymerization.

The thickness of the first positive C-plate is not particularly limited, and is preferably 10 μm or less, more preferably 0.1 to 5.0 μm, and still more preferably 0.3 to 2.0 μm.

Note that the thickness of the first positive C-plate is intended to refer to an average thickness of the first positive C-plate. The average thickness is obtained by measuring the thicknesses of any five or more points of the first positive C-plate and arithmetically averaging the measured values.

### (Positive A-Plate)

The positive A-plate is an optically anisotropic layer disposed next to the first positive C-plate and close to the polarizer in a circularly polarizing plate which will be described later.

The Re(550) which is an in-plane retardation of the positive A-plate at a wavelength of 550 nm is not particularly limited, and is preferably 55 to 95 nm, more preferably 65 to 95 nm, and still more preferably 65 to 85 nm from the viewpoint that the effect of the present invention is more excellent.

The positive A-plate may exhibit forward wavelength dispersion (a characteristic that the in-plane retardation decreases as the measurement wavelength increases) or reverse wavelength dispersibility (a characteristic that the in-plane retardation increases as the measurement wavelength increases). Note that the forward wavelength dispersion and the reverse wavelength dispersibility are preferably exhibited in a visible light range.

The configuration of the positive A-plate is not particularly limited, and examples thereof include a layer formed by fixing a rod-like liquid crystal compound horizontally aligned and a stretched film, among which a layer formed by fixing a rod-like liquid crystal compound horizontally aligned is preferable from the viewpoint that the effect of the present invention is more excellent.

Note that the state in which a rod-like liquid crystal compound is horizontally aligned means that a major axis of the rod-like liquid crystal compound and a main surface of the positive A-plate are parallel to each other. It is not required to be strictly parallel, and the angle formed by the major axis of the rod-like liquid crystal compound and the main surface of the positive A-plate is preferably in a range of 0°±20° and more preferably in a range of 0°±10°.

A known compound can be used as the rod-like liquid crystal compound.

Examples of the rod-like liquid crystal compound include the rod-like liquid crystal compounds exemplified in the first positive C-plate.

The rod-like liquid crystal compound may have a polymerizable group.

The types of polymerizable groups that the rod-like liquid crystal compound may have are as described above.

The positive A-plate is preferably a layer formed by fixing a rod-like liquid crystal compound having a polymerizable group by polymerization.

The thickness of the positive A-plate is not particularly limited, and is preferably 10 μm or less, more preferably 0.1 to 5.0 μm, and still more preferably 0.3 to 2.0 μm.

Note that the thickness of the positive A-plate is intended to refer to an average thickness of the positive A-plate. The average thickness is obtained by measuring the thicknesses of any five or more points of the positive A-plate and arithmetically averaging the measured values.

In addition, with regard to the optical laminate according to the embodiment of the present invention, in a case where the first positive C-plate and the positive A-plate are disposed adjacent to each other, a difference in refractive index between the first positive C-plate and the positive A-plate is 0.08 or less. In addition, with regard to the optical laminate according to the embodiment of the present invention, in a case where another layer is disposed between the first positive C-plate and the positive A-plate, a larger difference in refractive index of a difference in refractive index between the first positive C-plate and the other layer and a difference in refractive index between the positive A-plate and the other layer is 0.08 or less. From the viewpoint that the effect of the present invention is more excellent, the difference in refractive index is preferably 0.05 or less in any case. The lower limit of the difference in refractive index is not particularly limited, and may be, for example, 0.

The difference in refractive index is a value given by an absolute value of the difference in refractive index of each layer. Note that an average refractive index (average of nx, ny, and nz) of each layer at a wavelength of 550 nm is used as the refractive index.

The refractive index of each layer may be determined by obtaining the refractive index of each layer using an interference film thickness meter for each single layer. In addition, in the aspect of the optical laminate, the refractive index of each layer may be determined by obtaining a profile related to the film thickness of each layer and the refractive index of each layer using an interference film thickness meter, and fitting the obtained profile with each parameter.

In a case where the refractive index is obtained from a single layer or an optical laminate using an interference film thickness meter, the refractive index is obtained by measuring the refractive indices at five points in the plane and arithmetically averaging the obtained refractive indices. A microspectroscopic film thickness meter OPTM (manufactured by Otsuka Electronics Co., Ltd.) is used as the interference film thickness meter.

### (λ/4 Plate)

The λ/4 plate (a plate having a λ/4 function) is a plate having a function of converting linearly polarized light having a specific wavelength into circularly polarized light (or converting circularly polarized light having a specific wavelength into linearly polarized light). More specifically, the λ/4 plate is a plate whose in-plane retardation at a predetermined wavelength of/nm is λ/4 (or an odd multiple of λ/4).

Above all, from the viewpoint that the effect of the present invention is more excellent, the in-plane retardation Re(550) at a wavelength of 550 nm is preferably 100 to 200 nm, more preferably 120 to 160 nm, and still more preferably 130 to 150 nm.

Although the λ/4 plate may exhibit forward wavelength dispersion (a characteristic that the in-plane retardation decreases as the measurement wavelength increases) or reverse wavelength dispersibility (a characteristic that the in-plane retardation increases as the measurement wavelength increases), it is preferable that the λ/4 plate exhibits reverse wavelength dispersibility from the viewpoint that the effect of the present invention is more excellent. Note that the forward wavelength dispersion and the reverse wavelength dispersibility are preferably exhibited in a visible light range.

In order to make the in-plane retardation of the λ/4 plate appropriately reverse wavelength dispersibility, specifically, Re(450 nm)/Re(550 nm) of the λ/4 plate is preferably 0.70 or more and less than 1.00 and more preferably 0.80 to 0.90, and Re(650 nm)/Re(550 nm) of the λ/4 plate is preferably more than 1.00 and 1.20 or less and more preferably 1.02 to 1.10.

The configuration of the λ/4 plate is not particularly limited, and examples thereof include a layer formed by fixing a rod-like liquid crystal compound horizontally aligned and a stretched film, among which a layer formed by fixing a rod-like liquid crystal compound horizontally aligned is preferable from the viewpoint that the effect of the present invention is more excellent.

Note that the state in which a rod-like liquid crystal compound is horizontally aligned means that a major axis of the rod-like liquid crystal compound and a main surface of the λ/4 plate are parallel to each other. It is not required to be strictly parallel, and the angle formed by the major axis of the rod-like liquid crystal compound and the main surface of the λ/4 plate is preferably in a range of 0°±20° and more preferably in a range of 0°=10°.

The rod-like liquid crystal compound having reverse wavelength dispersibility is not particularly limited, and examples thereof include compounds represented by General Formula (1) described in JP2010-084032A (particularly, compounds described in paragraphs [0067] to [0073]), compounds represented by General Formula (II) described in JP2016-053709A (particularly, compounds described in paragraphs [0036] to [0043]), compounds represented by General Formula (1) described in JP2016-081035A (particularly, compounds described in paragraphs [0043] to [0055]), compounds represented by General Formula (1) described in WO2019/017444A (particularly, compounds described in paragraphs [0015] to [0036]), and compounds represented by General Formula (1) described in WO2019/017445A (particularly, compounds described in paragraphs [0015] to [0034]).

Note that the term “rod-like liquid crystal compound having reverse wavelength dispersibility” refers to a rod-like liquid crystal compound exhibiting reverse wavelength dispersibility in a case where a λ/4 plate is formed.

The rod-like liquid crystal compound having reverse wavelength dispersibility may have a polymerizable group. The types of polymerizable groups that the rod-like liquid crystal compound having reverse wavelength dispersibility may have are as described above.

The λ/4 plate is preferably a layer formed by fixing a rod-like liquid crystal compound having a polymerizable group and exhibiting reverse wavelength dispersibility by polymerization.

The thickness of the λ/4 plate is not particularly limited, and is preferably 10 μm or less, more preferably 0.1 to 5.0 μm, and still more preferably 0.3 to 3.0 μm.

Note that the thickness of the λ/4 plate is intended to refer to an average thickness of the λ/4 plate. The average thickness is obtained by measuring the thicknesses of any five or more points of the λ/4 plate and arithmetically averaging the measured values.

As shown in FIG. 2, the angle λ/4 formed by the in-plane slow axis of the positive A-plate 14 and the in-plane slow axis of the λ/4 plate 16 is in a range of 45°±10°. In other words, the angle θ is in a range of 35° to 55°. Above all, the angle θ is preferably 40° to 50° (45°±5°) and more preferably 42° to 48° (45°±3°) from the viewpoint that the effect of the present invention is more excellent.

Note that the angle θ is intended to refer to an angle formed by the in-plane slow axis of the positive A-plate 14 and the in-plane slow axis of the λ/4 plate 16 in a case of being viewed from the normal direction of the surface of the positive A-plate 14.

### (Second Positive C-Plate)

The second positive C-plate is a layer which may be disposed on a side of the λ/4 plate opposite to the polarizer side in a circularly polarizing plate which will be described later.

The Rth(550) which is a thickness direction retardation of the second positive C-plate at a wavelength of 550 nm is not particularly limited, and is preferably −55 to −25 nm, more preferably −55 to −35 nm, and still more preferably −45 to −35 nm from the viewpoint that the effect of the present invention is more excellent.

The configuration of the second positive C-plate is not particularly limited, and examples thereof include a layer formed by fixing a rod-like liquid crystal compound vertically aligned and a resin film, among which a layer formed by fixing a rod-like liquid crystal compound vertically aligned is preferable from the viewpoint that the effect of the present invention is more excellent.

Note that the state in which a rod-like liquid crystal compound is vertically aligned means that a major axis of the rod-like liquid crystal compound and a thickness direction of the second positive C-plate are parallel to each other. It is not required to be strictly parallel, and the angle formed by the major axis of the rod-like liquid crystal compound and the thickness direction of the second positive C-plate is preferably in a range of 0°±20° and more preferably in a range of 0°=10°.

A known compound can be used as the rod-like liquid crystal compound.

Examples of the rod-like liquid crystal compound include the rod-like liquid crystal compounds exemplified in the first positive C-plate.

The rod-like liquid crystal compound may have a polymerizable group.

The types of polymerizable groups that the rod-like liquid crystal compound may have are as described above.

The second positive C-plate is preferably a layer formed by fixing a rod-like liquid crystal compound vertically aligned and having a polymerizable group by polymerization.

The thickness of the second positive C-plate is not particularly limited, and is preferably 10 μm or less, more preferably 0.1 to 5.0 μm, and still more preferably 0.3 to 2.0 μm.

Note that the thickness of the second positive C-plate is intended to refer to an average thickness of the second positive C-plate. The average thickness is obtained by measuring the thicknesses of any five or more points of the second positive C-plate and arithmetically averaging the measured values.

### (Other Members)

The optical laminate may include layers other than the first positive C-plate, the positive A-plate, the λ/4 plate, and the second positive C-plate, as long as the effect of the present invention is not impaired.

### (Adhesion Layer)

The optical laminate may have an adhesion layer between the optically anisotropic layers.

Examples of the adhesion layer include a known pressure sensitive adhesive layer and a known adhesive layer.

The adhesive layer is a layer formed of an adhesive. Examples of the adhesive include a water-based adhesive, a solvent-based adhesive, an emulsion-based adhesive, a solvent-free adhesive, an active energy ray curable adhesive, and a thermosetting adhesive. Examples of the active energy ray curable adhesive include an electron beam curable adhesive, an ultraviolet curable adhesive, and a visible light curable adhesive, among which an ultraviolet curable adhesive is preferable. That is, the adhesion layer is preferably a layer formed of an ultraviolet curable adhesive.

Specific examples of the active energy ray curable adhesive include a (meth)acrylate-based adhesive. Examples of the curable component in the (meth)acrylate-based adhesive include a compound having a (meth)acryloyl group and a compound having a vinyl group.

The pressure sensitive adhesive layer is a layer formed of a pressure sensitive adhesive. Examples of the pressure sensitive adhesive include a rubber-based pressure sensitive adhesive, an acrylic pressure sensitive adhesive, a silicone-based pressure sensitive adhesive, an urethane-based pressure sensitive adhesive, a vinyl alkyl ether-based pressure sensitive adhesive, a polyvinyl alcohol-based pressure sensitive adhesive, a polyvinyl pyrrolidone-based pressure sensitive adhesive, a polyacrylamide-based pressure sensitive adhesive, and a cellulose-based pressure sensitive adhesive, among which an acrylic pressure sensitive adhesive (pressure sensitive adhesive) is preferable.

The acrylic pressure sensitive adhesive is preferably a copolymer of a (meth)acrylate in which the alkyl group in the ester moiety is an alkyl group having 20 or less carbon atoms such as a methyl group, an ethyl group, or a butyl group with a (meth)acrylic monomer having a functional group such as (meth)acrylic acid or hydroxyethyl (meth)acrylate.

As described in JP1999-149015A (JP-H11-149015A), it is generally preferable to adjust the refractive index of each layer (for example, an optically anisotropic layer) forming the optical laminate from the viewpoint of suppressing reflection. The difference in refractive index with an object to be bonded is preferably 0.1 or less, more preferably 0.08 or less, still more preferably 0.06 or less, and particularly preferably 0.03 or less. The difference in refractive index is obtained by the above-mentioned method.

In a case where the adhesion layer is disposed as the other layer described above, that is, in a case where the adhesion layer is disposed between the first positive C-plate and the positive A-plate, a larger difference in refractive index of a difference in refractive index between the first positive C-plate and the adhesion layer and a difference in refractive index between the positive A-plate and the adhesion layer is 0.08 or less.

In addition, the thickness of the adhesion layer is preferably 0.1 to 50 μm. From the viewpoint of layer thinning, the thickness of the adhesion layer is more preferably 25 μm or less, still more preferably 15 μm or less, and particularly preferably 5 μm or less. From the viewpoint of suppressing interference unevenness, the thickness of the adhesion layer is more preferably 5 μm or more, still more preferably 15 μm or more, and particularly preferably 25 μm or more.

In a case where the adhesion layer is disposed between the layers of the optically anisotropic layers formed by fixing a liquid crystal compound, an adhesive or pressure sensitive adhesive having a high refractive index may be used.

In order to increase the refractive index, it is also preferable to use a high-refractive monomer or high-refractive metal fine particles. That is, the refractive index of the adhesion layer can be adjusted by using an adhesion layer containing a high-refractive monomer or high-refractive metal fine particles.

The high-refractive monomer preferably has a benzene ring skeleton in a molecule thereof. Examples of the monofunctional monomer having a benzene ring skeleton in a molecule thereof include ethoxylated o-phenylphenol (meth)acrylate, o-phenylphenol glycidyl ether (meth)acrylate, para-cumylphenoxyethylene glycol (meth)acrylate, 2-methacryloyloxyethyl 2-acryloyloxyethyl phthalate, 2-acryloyloxyethyl-2-hydroxyethyl phthalate, 2-acryloyloxypropyl phthalate, phenoxyethyl (meth)acrylate, EO-modified phenol (meth)acrylate, phenoxydiethylene glycol (meth)acrylate, EO-modified nonylphenol (meth)acrylate, PO-modified nonylphenol (meth)acrylate, phenyl glycidyl ether (meth)acrylate, neopentyl glycol benzoate (meth)acrylate, nonylphenoxypolyethylene glycol (meth)acrylate, ECH-modified phenoxy (meth)acrylate, benzyl (meth)acrylate, and vinyl carbazole.

Examples of the high-refractive metal fine particles include inorganic particles. Examples of the component constituting the inorganic particles include a metal oxide, a metal nitride, a metal oxynitride, and a metal simple substance. Examples of the metal atom contained in the metal oxide, the metal nitride, the metal oxynitride, and the metal simple substance include a titanium atom, a silicon atom, an aluminum atom, a cobalt atom, and a zirconium atom. Specific examples of the inorganic particles include inorganic oxide particles such as alumina (aluminum oxide) particles, alumina hydrate particles, silica (silicon oxide) particles, zirconia (zirconium oxide) particles, and clay minerals (for example, smectite). Zirconium oxide particles are preferable from the viewpoint of refractive index.

The refractive index can be adjusted to a predetermined value by changing the amount of inorganic particles.

The average particle diameter of the inorganic particles is not particularly limited. In a case where zirconium oxide is used as a main component, the average particle diameter of the zirconium oxide particles is preferably 1 to 120 nm, more preferably 1 to 60 nm, and still more preferably 2 to 40 nm.

### (Alignment Film)

The optical laminate may further have an alignment film. The alignment film may be disposed between the optically anisotropic layers (for example, between the first positive C-plate and the positive A-plate, between the positive A-plate and the λ/4 plate, and between the λ/4 plate and the second positive C-plate).

Note that, as shown in FIG. 1, the optical laminate 10 preferably does not have an alignment film between the optically anisotropic layers (the first positive C-plate 12, the positive A-plate 14, the λ/4 plate 16, and the second positive C-plate 18).

The alignment film can be formed by means such as rubbing treatment of an organic compound (preferably a polymer), oblique vapor deposition of an inorganic compound, formation of a layer having microgrooves, or accumulation of an organic compound (for example, ω-tricosanoic acid, dioctadecylmethylammonium chloride, or methyl stearate) by the Langmuir-Blodgett method (LB film).

Further, an alignment film is also known that exhibits an alignment function by application of an electric field, application of a magnetic field, or irradiation with light (preferably polarized light).

The alignment film is preferably formed by a rubbing treatment of a polymer.

Examples of the alignment film include a photo-alignment film.

The thickness of the alignment film is not particularly limited as long as it can exhibit an alignment function, and is preferably 0.01 to 5.0 μm, more preferably 0.05 to 2.0 μm, and still more preferably 0.1 to 0.5 μm.

### (Substrate)

The optical laminate may further have a substrate.

The substrate is preferably a transparent substrate. The transparent substrate is intended to refer to a substrate having a visible light transmittance of 60% or more, which preferably has a visible light transmittance of 80% or more and more preferably 90% or more. The upper limit of the visible light transmittance of the substrate is not particularly limited, and is preferably 99.9% or less.

The thickness of the substrate is not particularly limited, and is preferably 10 to 200 μm, more preferably 10 to 100 μm, and still more preferably 20 to 90 μm.

In addition, the substrate may consist of a plurality of layers laminated. The substrate may undergo a surface treatment (for example, a glow discharge treatment, a corona discharge treatment, an ultraviolet (UV) treatment, or a flame treatment) on the surface of the substrate in order to improve adhesion with layers provided thereon.

In addition, an adhesive layer (undercoat layer) may be provided on the substrate.

The substrate may be a so-called temporary support. For example, after manufacturing an optically anisotropic layer (a first positive C-plate, a positive A-plate, a λ/4 plate, or a second positive C-plate) on the substrate, the substrate may be peeled off from the optically anisotropic layer, if necessary.

### (Method for Manufacturing Optical Laminate)

The method for manufacturing an optical laminate is not particularly limited, and a known method can be used.

For example, an optical laminate can be manufactured by preparing each of a first positive C-plate, a positive A-plate, a λ/4 plate, and a second positive C-plate, and bonding these layers together in a predetermined order through an adhesion layer (for example, a pressure sensitive adhesive layer or an adhesive layer).

In addition, each of the first positive C-plate, the positive A-plate, the λ/4 plate, and the second positive C-plate can be manufactured using a composition for forming an optically anisotropic layer, which contains a liquid crystal compound having a polymerizable group.

The method for manufacturing an optical laminate may be a method of directly forming an optically anisotropic layer on an optically anisotropic layer (for example, a first positive C-plate, a positive A-plate, a λ/4 plate, or a second positive C-plate). In addition, an aspect in which an optically anisotropic layer is in direct contact with an optically anisotropic layer can be manufactured, for example, by forming an optically anisotropic layer using a composition for forming an optically anisotropic layer, which contains a material that imparts an alignment control ability to the surface of the optically anisotropic layer (for example, a photo-alignment polymer), and applying a composition for forming an optically anisotropic layer thereon to form an optically anisotropic layer.

Hereinafter, a method for manufacturing an optically anisotropic layer (a first positive C-plate, a positive A-plate, a λ/4 plate, or a second positive C-plate) using a composition for forming an optically anisotropic layer containing a liquid crystal compound having a polymerizable group will be described in detail.

The liquid crystal compound having a polymerizable group (hereinafter, also referred to as “polymerizable liquid crystal compound”) contained in the composition for forming an optically anisotropic layer is as described above. Note that, as described above, the rod-like liquid crystal compound is appropriately selected depending on the characteristics of an optically anisotropic layer to be formed.

The content of the polymerizable liquid crystal compound in the composition for forming an optically anisotropic layer is preferably 60% to 99% by mass and more preferably 70% to 98% by mass with respect to the total solid content of the composition for forming an optically anisotropic layer.

Note that the solid content refers to a component capable of forming an optically anisotropic layer from which a solvent has been removed, and even in a case where a component itself is in a liquid state, such a component is regarded as the solid content.

The composition for forming an optically anisotropic layer may contain a compound other than the liquid crystal compound having a polymerizable group.

The composition for forming an optically anisotropic layer may contain a polymerization initiator. The polymerization initiator to be used is selected according to the type of polymerization reaction, and examples thereof include a thermal polymerization initiator and a photopolymerization initiator.

The content of the polymerization initiator in the composition for forming an optically anisotropic layer is preferably 0.01% to 20% by mass and more preferably 0.5% to 10% by mass with respect to the total solid content of the composition for forming an optically anisotropic layer.

Examples of other components that may be contained in the composition for forming an optically anisotropic layer include, in addition to the foregoing components, a polyfunctional monomer, a photo-acid generator, an alignment control agent (a vertical alignment agent or a horizontal alignment agent), a surfactant, an adhesion improver, a plasticizer, and a solvent.

Examples of the method of applying the composition for forming an optically anisotropic layer include a curtain coating method, a dip coating method, a spin coating method, a printing coating method, a spray coating method, a slot coating method, a roll coating method, a slide coating method, a blade coating method, a gravure coating method, and a wire bar method.

Next, the formed coating film is subjected to an alignment treatment to align a polymerizable liquid crystal compound in the coating film. For example, in a case where the first positive C-plate is formed, a rod-like liquid crystal compound is vertically aligned. In addition, in a case where the positive A-plate is formed, a rod-like liquid crystal compound is horizontally aligned. In addition, in a case where the λ/4 plate is formed, a rod-like liquid crystal compound is horizontally aligned. In addition, in a case where the second positive C-plate is formed, a rod-like liquid crystal compound is vertically aligned.

The alignment treatment can be carried out by drying the coating film at room temperature or by heating the coating film. In a case of a thermotropic liquid crystal compound, the liquid crystal phase formed by the alignment treatment can generally be transferred by a change in temperature or pressure. In a case of a lyotropic liquid crystal compound, the liquid crystal phase formed by the alignment treatment can also be transferred by a compositional ratio such as an amount of solvent.

Note that the conditions in a case of heating the coating film are not particularly limited, and the heating temperature is preferably 50° C. to 250° C. and more preferably 50° C. to 150° C., and the heating time is preferably 10 seconds to 10 minutes.

In addition, after heating the composition layer and before a curing treatment (light irradiation treatment) which will be described later, the coating film may be cooled, if necessary. The cooling temperature is preferably 20° C. to 200° C. and more preferably 30° C. to 150° C.

Next, the coating film in which the polymerizable liquid crystal compound is aligned is subjected to a curing treatment.

The method of the curing treatment carried out on the coating film in which the polymerizable liquid crystal compound is aligned is not particularly limited, and examples thereof include a light irradiation treatment and a heat treatment. Above all, from the viewpoint of manufacturing suitability, a light irradiation treatment is preferable, and an ultraviolet irradiation treatment is more preferable.

The irradiation condition of the light irradiation treatment is not particularly limited, and an irradiation amount of 50 to 1,000 mJ/cm² is preferable.

The atmosphere during the light irradiation treatment is not particularly limited and is preferably a nitrogen atmosphere.

The optical laminate can be applied to various applications, and can be particularly suitably applied to an antireflection application. More specifically, the optical laminate can be suitably applied to an antireflection application for a display device such as an organic electroluminescent (organic EL) display device.

### <Circularly Polarizing Plate>

The above-mentioned optical laminate can be used as the circularly polarizing plate according to the embodiment of the present invention in combination with a polarizer.

That is, the circularly polarizing plate according to the embodiment of the present invention is a circularly polarizing plate having a polarizer and an optical laminate, in which the optical laminate has, from the polarizer side, a first positive C-plate, a positive A-plate, and a λ/4 plate, the in-plane slow axis of the positive A-plate and the absorption axis of the polarizer are parallel to each other, and the angle formed by the in-plane slow axis of the positive A-plate and the in-plane slow axis of the λ/4 plate is 45°±10°. In a case where the first positive C-plate and the positive A-plate are disposed adjacent to each other, the difference in refractive index between the first positive C-plate and the positive A-plate is 0.08 or less and in a case where another layer is disposed between the first positive C-plate and the positive A-plate, a larger difference in refractive index of a difference in refractive index between the first positive C-plate and the other layer and a difference in refractive index between the positive A-plate and the other layer is 0.08 or less.

The circularly polarizing plate according to the embodiment of the present invention will be described with reference to the accompanying drawings. FIG. 3 shows a cross-sectional view of the circularly polarizing plate according to the embodiment of the present invention.

A circularly polarizing plate 20 has a polarizer 22, the first positive C-plate 12, the positive A-plate 14, and the λ/4 plate 16 in this order. As shown in FIG. 3, the second positive C-plate 18 may be provided on a side of the λ/4 plate 16 that is far from the polarizer 22 (a side opposite to the polarizer 22 side).

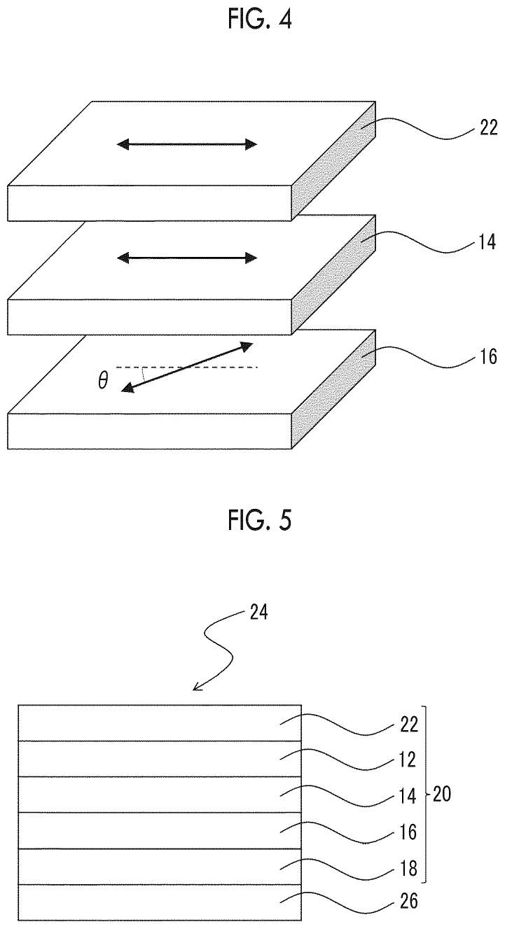

In addition, FIG. 4 shows a relationship among the absorption axis of the polarizer 22, the in-plane slow axis of the positive A-plate 14, and the in-plane slow axis of the λ/4 plate 16. In FIG. 4, the arrow in the polarizer 22 indicates a direction of the absorption axis, and the arrow in the positive A-plate 14 and the λ/4 plate 16 indicates a direction of the in-plane slow axis in each layer. In FIG. 4, the in-plane slow axis of the positive A-plate 14 and the absorption axis of the polarizer 22 are parallel to each other, and an angle θ formed by the in-plane slow axis of the positive A-plate 14 and the in-plane slow axis of the λ/4 plate 16 is 45°±10°.

Hereinafter, each member included in the circularly polarizing plate 20 will be described in detail.

Note that the aspects of the first positive C-plate 12, the positive A-plate 14, the λ/4 plate 16, and the second positive C-plate 18 included in the circularly polarizing plate 20 are as described above in the section of <Optical laminate>.

In addition, the circularly polarizing plate according to the embodiment of the present invention using the preferred aspect of the above-mentioned optical laminate is a preferred aspect of the circularly polarizing plate according to the embodiment of the present invention.

### (Polarizer)

The polarizer may be a member having a function of converting natural light into specific linearly polarized light, and examples thereof include an absorption type polarizer.

The type of the polarizer is not particularly limited, and a commonly used polarizer can be used. Examples of the polarizer include an iodine-based polarizer, a dye-based polarizer using a dichroic dye, and a polyene-based polarizer. The iodine-based polarizer and the dye-based polarizer are generally prepared by adsorbing iodine or a dichroic dye on a polyvinyl alcohol, followed by stretching.

Note that a protective film may be disposed on one side or both sides of the polarizer.

In addition, as described in WO2019/131943A and JP2017-83843A, a coating type polarizer prepared by using and applying a liquid crystal compound and a dichroic organic coloring agent (for example, a dichroic azo coloring agent used for a light-absorbing anisotropic film described in WO2017/195833A) without using a polyvinyl alcohol as a binder may be used as the polarizer. That is, the polarizer may be a polarizer formed of a composition containing a polymerizable liquid crystal compound.

This coating type polarizer is a technique that utilizes the alignment of a liquid crystal compound to align a dichroic organic coloring agent. As described in JP2012-83734A, in a case where the polymerizable liquid crystal compound exhibits smectic properties, it is preferable from the viewpoint of increasing the alignment degree. Alternatively, as described in WO2018/186503A, it is also preferable to crystallize the coloring agent from the viewpoint of increasing the alignment degree. WO2019/131943A describes a structure of a polymer liquid crystal that is preferable for increasing the alignment degree.

A polarizer in which a dichroic organic coloring agent is aligned using the aligning properties of a liquid crystal without carrying out stretching has the following characteristics. The above-mentioned polarizer has many advantages, such as being able to be made very thin with a thickness of about 0.1 to 5 μm; as described in JP2019-194685A, being difficult for cracks to occur in a case of being bent, and being less likely to undergo thermal deformation; and as described in Japanese Patent No. 6483486, exhibiting excellent durability even with a polarizing plate having a high transmittance of more than 50%.

Taking advantage of these advantages, it is possible to use such a polarizer for applications where high brightness and small size and light weight are required, applications in a minute optical system, applications in molding to a portion having a curved surface, and applications in a flexible portion. Of course, it is also possible to peel off the support and transfer the polarizer for use.

From the viewpoint of power saving, the transmittance of the polarizer is preferably 40% or more, more preferably 44% or more, and still more preferably 50% or more in terms of luminosity corrected single transmittance. In the present invention, the luminosity corrected single transmittance of the polarizer is measured using an automatic polarizing film measuring device: VAP-7070 (manufactured by JASCO Corporation). The luminosity corrected single transmittance can be measured as follows. A sample (5 cm×5 cm) in which the polarizer is attached onto glass through a pressure sensitive adhesive is prepared. At this time, a polarizer protective film is attached to the polarizer so that the polarizer protective film is on the side opposite to the glass (air interface side). The luminosity corrected single transmittance is measured by setting the glass side of the sample toward a light source.

As shown in FIG. 4, the absorption axis of the polarizer 22 and the in-plane slow axis of the positive A-plate 14 are parallel to each other. The definition of “parallel” is as described above; in other words, the angle formed by the absorption axis of the polarizer 22 and the in-plane slow axis of the positive A-plate 14 is −20° to 20°. Above all, from the viewpoint that the effect of the present invention is more excellent, the angle formed by the absorption axis of the polarizer 22 and the in-plane slow axis of the positive A-plate 14 is more preferably −5° to 5° and still more preferably −3° to 3°.

Note that the angle is intended to refer to an angle formed by the absorption axis of the polarizer 22 and the in-plane slow axis of the positive A-plate 14 in a case of being viewed from the normal direction of a surface of the polarizer 22.

In addition, as shown in FIG. 4, an angle θ formed by the absorption axis of the polarizer 22 and the in-plane slow axis of the λ/4 plate 16 is 45°±10°. That is, the angle θ formed by the absorption axis of the polarizer 22 and the in-plane slow axis of the λ/4 plate 16 is 35° to 55°. Above all, from the viewpoint that the effect of the present invention is more excellent, the angle θ formed by the absorption axis of the polarizer 22 and the in-plane slow axis of the λ/4 plate 16 is preferably 40° to 50° (45°±5°) and more preferably 42° to 48° (45°±3°).

Note that the angle θ is intended to refer to an angle formed by the absorption axis of the polarizer 22 and the in-plane slow axis of the λ/4 plate 16 in a case of being viewed from the normal direction of a surface of the polarizer 22.

The circularly polarizing plate may have a member other than the optical laminate and the polarizer.

The circularly polarizing plate may have an adhesion layer between the optical laminate and the polarizer.

Examples of the adhesion layer include a known pressure sensitive adhesive layer and a known adhesive layer.

As for the adhesion layer, the adhesion layer described in the section of <Optical laminate> can be used.

The method for manufacturing the above-mentioned circularly polarizing plate is not particularly limited and may be, for example, a known method.

For example, a method of bonding a polarizer and an optical laminate through an adhesion layer can be mentioned.

### <Organic Electroluminescent Display Device>

The organic electroluminescent display device according to the embodiment of the present invention has the above-mentioned circularly polarizing plate. Usually, the circularly polarizing plate is provided on an organic electroluminescent display panel of an organic electroluminescent display device. That is, the organic electroluminescent display device according to the embodiment of the present invention has an organic electroluminescent display panel and the above-mentioned circularly polarizing plate.

An example of the organic electroluminescent display device includes an aspect which has an organic electroluminescent display panel, an optical laminate, and a polarizer in this order (see FIG. 5).

More specifically, an organic electroluminescent display device 24 (organic EL display device 24) shown in FIG. 5 has an organic electroluminescent display panel 26 (organic EL display panel 26) and a circularly polarizing plate 20. Note that the circularly polarizing plate 20 has the same aspect as shown in FIG. 3, and the circularly polarizing plate 20 is disposed such that the second positive C-plate 18 and the organic EL display panel 26 face each other. That is, the organic EL display device 24 has the organic EL display panel 26, the second positive C-plate 18, the λ/4 plate 16, the positive A-plate 14, the first positive C-plate 12, and the polarizer 22 in this order.

The organic electroluminescent display panel that is used in the organic electroluminescent display device according to the embodiment of the present invention is a member in which a light emitting layer or a plurality of organic compound thin films including a light emitting layer are formed between a pair of electrodes of an anode and a cathode, and may have a hole injection layer, a hole transport layer, an electron injection layer, an electron transport layer, a protective layer, and the like in which each of these layers may have other functions, in addition to the light emitting layer. Various materials can be used to form each layer.

### <Display Device>

The above-mentioned circularly polarizing plate can also be used in a variety of display devices having a curved surface. For example, the above-mentioned circularly polarizing plate can be used for a rollable display, an in-vehicle display, a lens of sunglasses, a lens of goggles for an display device, and the like, each of which has a curved surface.

The circularly polarizing plate according to the embodiment of the present invention can be bonded onto a curved surface or can be integrally molded with a resin, which contributes to an improvement in design. The display device (preferably, an organic electroluminescent display device) using the circularly polarizing plate according to the embodiment of the present invention is preferably used for a curved display or an in-vehicle display because the display device exhibits a small change in tint in a case of being observed from an oblique direction at all azimuthal angles.

The circularly polarizing plate according to the embodiment of the present invention is also preferably used for in-vehicle display optical systems such as a head-up display, optical systems such as AR glasses and VR glasses, optical sensors such as light detection and ranging (LiDAR), a face recognition system, and polarization imaging, and the like. In addition, it is also preferable that the circularly polarizing plate according to the embodiment of the present invention is used in a display device having a curved surface by being disposed along the curved surface.

### EXAMPLES

Hereinafter, the present invention will be described in more detail with reference to Examples. The materials, the amounts of materials used, the proportions, the treatment details, the treatment procedure, and the like shown in the Examples below can be appropriately modified without departing from the spirit of the present invention. Therefore, the scope of the present invention should not be construed as being limited to the specific Examples set forth below.

### Example 1

### (Preparation of First Positive C-Plate)

### [Preparation of Cellulose Acylate Film]

The following composition was put into a mixing tank, stirred, and further heated at 90° C. for 10 minutes to obtain a composition. Then, the obtained composition was filtered through a filter paper having an average pore diameter of 34 μm and a sintered metal filter having an average pore diameter of 10 μm to prepare a dope. The concentration of solid contents of the dope is 23.5% by mass, and the solvent of the dope is methylene chloride/methanol/butanol=81/18/1 (mass ratio).

Cellulose acylate dope

| | | |
|---|---|---|
| Cellulose acylate (acetyl substitution degree: 2.86, viscosity average polymerization degree: | 100 | parts by mass |
| 310) | | |
| Sugar ester compound 1 (represented by Formula (S4)) | 6.0 | parts by mass |
| Sugar ester compound 2 (represented by Formula (S5)) | 2.0 | parts by mass |
| Silica particle dispersion (AEROSIL R972, manufactured by Nippon Aerosil Co., Ltd.) | 0.1 | parts by mass |
| Solvent (methylene chloride/methanol/butanol) | | |

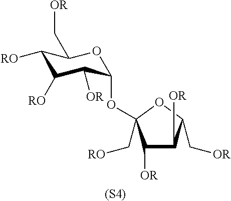

(R = benzoyl or H
Average substitution degree: 5.7) 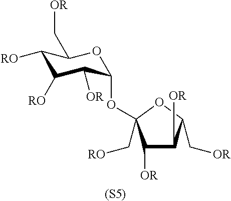
(R = acetyl/isobutyryl = 2/6)

The dope prepared above was cast using a drum film forming machine. The dope was cast from a die such that the dope was in contact with a metal support cooled to 0° C., and then the resulting web (film) was stripped off. The drum was made of SUS.

After the web (film) obtained by casting was peeled off from the drum, the web was dried in a tenter device for 20 minutes at 30° C. to 40° C. at the time of transporting the film, using a tenter device that clips both ends of the web with clips and then transports the web. Subsequently, the web was post-dried by zone heating while being rolled and transported. The obtained web was knurled and then wound up.

The obtained cellulose acylate film had a film thickness of 40 μm, an in-plane retardation of 1 nm at a wavelength of 550 nm, and a thickness direction retardation of 26 nm at a wavelength of 550 nm.

### [Preparation of First Positive C-Plate]

A composition 1 containing a rod-like liquid crystal compound and having the following composition was applied onto the above prepared cellulose acylate film using a geeser coating machine to form a composition layer. After that, both ends of the film were held, a cooling plate (9° C.) was installed on the side of the surface on which the coating film of the film was formed so that the distance from the film was 5 mm, and a heater (75° C.) was installed on the side opposite to the surface on which the coating film of the film was formed so that the distance from the film was 5 mm, followed by drying for 2 minutes.

Next, the obtained film was heated with hot air at 60° C. for 1 minute, and irradiated with ultraviolet rays at an irradiation amount of 100 mJ/cm² using a 365 nm UV-LED while purging with nitrogen so that the atmosphere had an oxygen concentration of 100 ppm by volume or less. Thereafter, the obtained coating film was annealed with hot air at 120° C. for 1 minute to form a first positive C-plate on the film.

The surface of the obtained first positive C-plate opposite to the film side was irradiated with UV light (ultra-high pressure mercury lamp; UL750, manufactured by HOYA Corporation) at an irradiation amount of 7.9 mJ/cm² (wavelength: 313 nm) through a wire grid polarizer at room temperature to form a composition layer having an alignment control ability on the surface thereof.

The formed first positive C-plate had a film thickness of 0.49 μm. The formed first positive C-plate had an in-plane retardation Re of 0 nm at a wavelength of 550 nm, and a thickness direction retardation Rth of −55 nm at a wavelength of 550 nm. It was confirmed that the average tilt angle of the major axis direction of the rod-like liquid crystal compound with respect to the film plane was 90° and the rod-like liquid crystal compound was aligned vertically to the film plane.

Composition 1

| | | |
|---|---|---|
| Rod-like liquid crystal compound (A) given below | 100 | parts by mass |
| Polymerizable monomer (A-400, manufactured by Shin-Nakamura Chemical Co., Ltd.) | 4.2 | parts by mass |
| Polymerization initiator S-1 (oxime type) given below | 5.1 | parts by mass |
| Photoacid generator D-1 given below | 3.0 | parts by mass |
| Polymer M-1 given below | 5.1 | parts by mass |
| Vertical alignment agent S01 given below | 1.9 | parts by mass |
| Photo-alignment polymer A-1 given below | 0.8 | parts by mass |
| Methyl isobutyl ketone | 567.0 | parts by mass |

Rod-like liquid crystal compound (A) (hereinafter, a mixture of compounds. Numerical values represent mass ratios.) 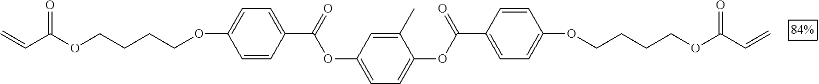 [SMILES: C=CC(=O)OCCCCOc1ccc(C(=O)Oc2ccc(OC(=O)c3ccc(OCCCCOC(=O)C=C)cc3)c(C)c2)cc1] 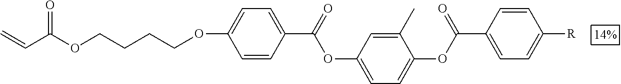 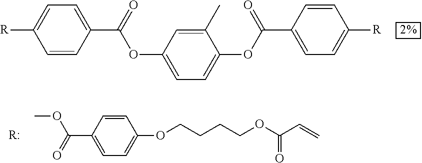
Polymerization initiator S-1 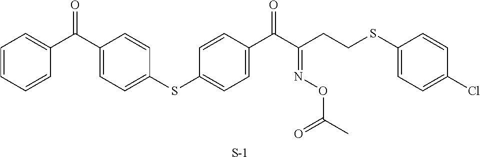
Photoacid generator D-1 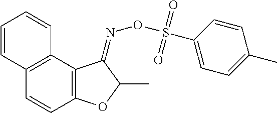 [SMILES: Cc1ccc(S(=O)(=O)O/N=C2/c3c(ccc4ccccc34)OC2C)cc1]
Polymer M-1 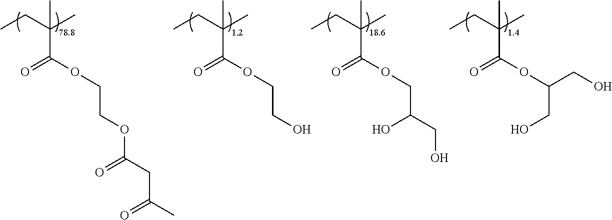
Vertical alignment agent S01

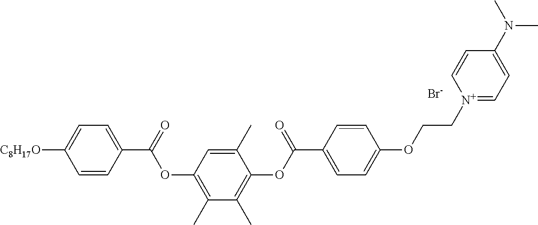

Photo-alignment polymer A-1 (in the following formula: a to c are a:b:c=17:64:19, and represent the content of each repeating unit with respect to all the repeating units in the polymer. Weight-average molecular weight: 80,000)

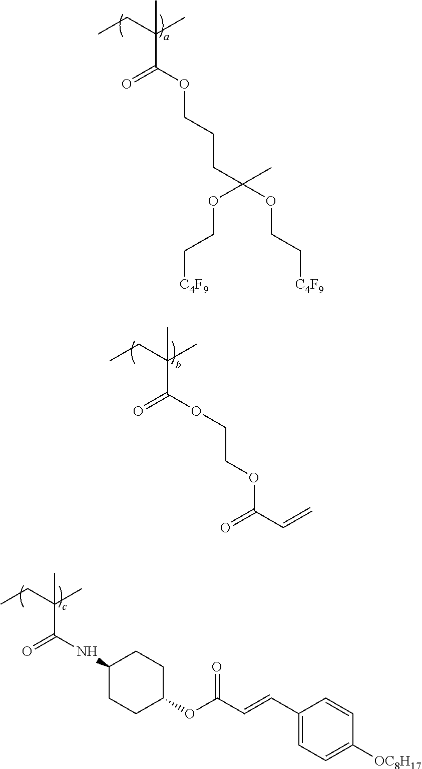

### (Formation of Positive A-Plate)

Next, a composition 2 containing a rod-like liquid crystal compound and having the following composition was applied onto the first positive C-plate prepared above using a geeser coating machine, and heated with hot air at 80° C. for 60 seconds. Subsequently, the obtained composition layer was irradiated with UV (500 mJ/cm²) at 80° C. to immobilize the alignment of the liquid crystal compound to form a positive A-plate.

The positive A-plate had a thickness of 0.53 μm and an Re(550) of 75 nm at a wavelength of 550 nm. Assuming that the width direction of the film is defined as 0° (the longitudinal direction of the film is defined as 90°), the in-plane slow axis direction (alignment axis angle of the liquid crystal compound) was 90°.

Composition 2

| | | |
|---|---|---|
| Rod-like liquid crystal compound (A) given above | 100 | parts by mass |
| Ethylene oxide-modified trimethylolpropane triacrylate (V# 360, manufactured by Osaka | 4 | parts by mass |
| Organic Chemical Industry Ltd.) | | |
| Photopolymerization initiator (IRGACURE 819, manufactured by BASF SE) | 3 | parts by mass |
| Fluorine-containing compound A given below | 0.08 | parts by mass |
| Methyl ethyl ketone | 156 | parts by mass |

Fluorine-containing compound A

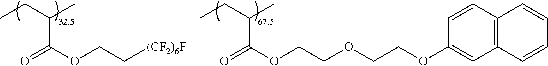

A laminate 1 in which a first positive C-plate and a positive A-plate were directly laminated on an elongated cellulose acylate film was prepared by the above-mentioned procedure.

### (Preparation of Second Positive C-Plate)

The composition 1 was applied onto the above prepared cellulose acylate film using a geeser coating machine to form a composition layer. After that, both ends of the film were held, a cooling plate (9° C.) was installed on the side of the surface on which the coating film of the film was formed so that the distance from the film was 5 mm, and a heater (75° C.) was installed on the side opposite to the surface on which the coating film of the film was formed so that the distance from the film was 5 mm, followed by drying for 2 minutes.

Next, the obtained film was heated with hot air at 60° C. for 1 minute, and irradiated with ultraviolet rays at an irradiation amount of 100 mJ/cm² using a 365 nm UV-LED while purging with nitrogen so that the atmosphere had an oxygen concentration of 100 ppm by volume or less. Thereafter, the obtained coating film was annealed with hot air at 120° C. for 1 minute to form a second positive C-plate.

The surface of the obtained second positive C-plate opposite to the film side was irradiated with UV light (ultra-high pressure mercury lamp; UL750, manufactured by HOYA Corporation) at an irradiation amount of 7.9 mJ/cm² (wavelength: 313 nm) through a wire grid polarizer at room temperature to form a composition layer having an alignment control ability on the surface thereof.

The formed second positive C-plate had a film thickness of 0.35 μm. The formed second positive C-plate had an in-plane retardation Re of 0 nm at a wavelength of 550 nm, and a thickness direction retardation Rth of −40 nm at a wavelength of 550 nm. It was confirmed that the average tilt angle of the major axis direction of the rod-like liquid crystal compound with respect to the film plane was 90° and the rod-like liquid crystal compound was aligned vertically to the film plane.

### (Preparation of λ/4 Plate)

Next, a composition 3 containing a rod-like liquid crystal compound and having the following composition was applied onto the second positive C-plate prepared above using a geeser coating machine, heated once to 120° C. with hot air, and then cooled to 60° C. to stabilize the alignment. Thereafter, a first irradiation with ultraviolet rays (80 mJ/cm²) was carried out using an ultra-high pressure mercury lamp in a nitrogen atmosphere (an oxygen concentration of less than 100 ppm) while keeping the film temperature at 60° C. Thereafter, the film temperature was kept at 100° C., and the alignment was immobilized by a second irradiation with ultraviolet rays (300 mJ/cm²) to form a λ/4 plate.

The λ/4 plate had a thickness of 2.8 μm and an Re(550) of 141 nm at a wavelength of 550 nm. Assuming that the width direction of the film is defined as 0° (the longitudinal direction of the film is defined as 90°), the in-plane slow axis direction (alignment axis angle of the liquid crystal compound) was 45°.

Composition 3

| | | |
|---|---|---|
| Rod-like liquid crystal compound (A) given above | 8.5 | parts by mass |
| Rod-like liquid crystal compound (B) given below | 21.2 | parts by mass |
| Rod-like liquid crystal compound (C) given below | 26.1 | parts by mass |
| Rod-like liquid crystal compound (D) given below | 29.0 | parts by mass |
| Compound (1) given below | 15.3 | parts by mass |
| Polymerizable compound M1 given below | 5.0 | parts by mass |
| Polymerization initiator S-1 (oxime type) given above | 0.5 | parts by mass |
| Fluorine-containing compound B given below | 0.1 | parts by mass |
| Cyclopentanone | 175.0 | parts by mass |
| Methyl ethyl ketone | 50.0 | parts by mass |
| Ethyl laurate | 10.0 | parts by mass |

Rod-like liquid crystal compound (B) 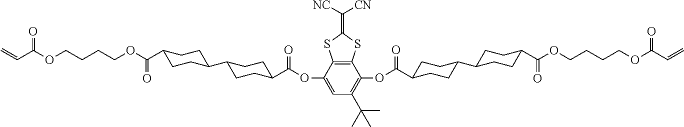 [SMILES: C=CC(=O)OCCCCOC(=O)C1CCC(C2CCC(C(=O)Oc3cc(C(C)(C)C)c(OC(=O)C4CCC(C5CCC(C(=O)OCCCCOC(=O)C=C)CC5)CC4)c4c3SC(=C(C#N)C#N)S4)CC2)CC1]
Rod-like liquid crystal compound (C) 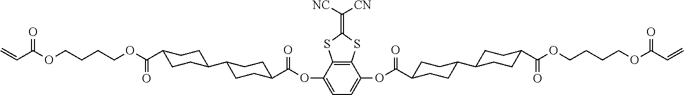 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c4c3SC(=C(C#N)C#N)S4)CC2)CC1]
Rod-like liquid crystal compound (D) 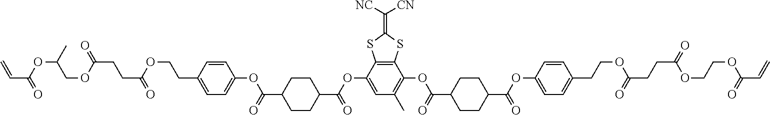 [SMILES: C=CC(=O)OCCOC(=O)CCC(=O)OCCc1ccc(OC(=O)C2CCC(C(=O)Oc3c(C)cc(OC(=O)C4CCC(C(=O)Oc5ccc(CCOC(=O)CCC(=O)OCC(C)OC(=O)C=C)cc5)CC4)c4c3SC(=C(C#N)C#N)S4)CC2)cc1]
Compound (1) 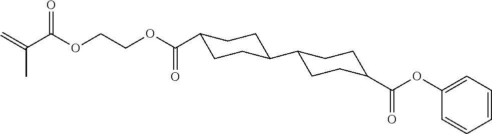 [SMILES: C=C(C)C(=O)OCCOC(=O)C1CCC(C2CCC(C(=O)Oc3ccccc3)CC2)CC1]
Polymerizable compound M1 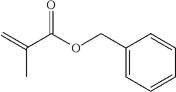
Fluorine-containing compound B

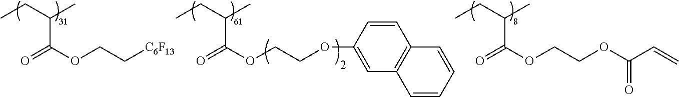

A laminate 2 in which a second positive C-plate and a λ/4 plate were directly laminated on an elongated cellulose acylate film was prepared by the above-mentioned procedure.

The surface side of the positive A-plate of the above prepared laminate 1 and the surface side of the λ/4 plate of the above prepared laminate 2 were continuously bonded to each other using an ultraviolet curable adhesive.

Subsequently, the cellulose acylate film on the laminate 1 side was peeled off to expose the surface of the first positive C-plate in contact with the cellulose acylate film. In this manner, an optical laminate 1 was obtained in which a second positive C-plate, a λ/4 plate, a positive A-plate, and a first positive C-plate were laminated in this order on a cellulose acylate film.

### (Preparation of Linearly Polarizing Plate)

The surface of a support of a cellulose triacetate film TJ25 (manufactured by FUJIFILM Corporation, thickness: 25 μm) was subjected to an alkali saponification treatment. Specifically, the support was immersed in a 1.5 N sodium hydroxide aqueous solution at 55° C. for 2 minutes, washed in a water washing bath at room temperature, and further neutralized with 0.1 N sulfuric acid at 30° C. After neutralization, the support was washed in the water washing bath at room temperature and further dried with hot air at 100° C. to obtain a polarizer protective film.

A roll-like polyvinyl alcohol (PVA) film having a thickness of 60 μm was continuously stretched in an iodine aqueous solution in a longitudinal direction and dried to obtain a polarizer having a thickness of 13 μm. The luminosity corrected single transmittance of the polarizer was 43%. At this time, the absorption axis direction and the longitudinal direction of the polarizer coincided.

The polarizer protective film was bonded to one surface of the polarizer using the following PVA adhesive to prepare a linearly polarizing plate.

### [Preparation of PVA Adhesive]

100 parts by mass of a polyvinyl alcohol-based resin having an acetoacetyl group (average degree of polymerization: 1200, degree of saponification: 98.5 mol %, and degree of acetoacetylation: 5 mol %) and 20 parts by mass of methylol melamine were dissolved in pure water under a temperature condition of 30° C. to prepare a PVA adhesive as an aqueous solution adjusted to a concentration of solid contents of 3.7% by mass.

### (Preparation of Circularly Polarizing Plate)

The surface of the first positive C-plate of the above prepared elongated optical laminate 1 and the surface of the polarizer (the surface opposite to the polarizer protective film) of the above prepared elongated linearly polarizing plate were continuously bonded to each other using an ultraviolet curable adhesive such that the two surfaces faced each other. Subsequently, the cellulose acylate film of the optical laminate 1 on the second positive C-plate side was peeled off to expose the surface of the second positive C-plate that was in contact with the cellulose acylate film, thereby obtaining a circularly polarizing plate 1.

The refractive indices of the positive A-plate and the first positive C-plate were 1.59 and 1.57, respectively, and the difference in refractive index between the positive A-plate and the first positive C-plate was 0.02.

### Example 2 to Example 9 and Comparative Example 1

A circularly polarizing plate was prepared in the same manner as in Example 1, except that the thicknesses at the time of [Preparation of first positive C-plate], [Preparation of positive A-plate], and [Preparation of second positive C-plate] were changed as shown in Table 1 which will be given later.

### Example 10

### (Preparation of Positive A-Plate)

### [Alkali Saponification Treatment]

The cellulose acylate film obtained in the same manner as in Example 1 was subjected to an alkali saponification treatment by the following procedure.

The above-mentioned cellulose acylate film was passed through a dielectric heating roll at a temperature of 60° C. to raise a film surface temperature to 40° C. After that, an alkaline solution having the following composition was applied onto the band surface of the film at an application amount of 14 mL/m2 using a bar coater, and then transported for 10 seconds under a steam type far-infrared heater manufactured by Noritake Company Limited, which was heated to 110° C. Subsequently, 3 mL/m2 of pure water was applied thereto using the same bar coater. Then, after washing with water using a fountain coater and draining using an air knife were repeated three times, the film was transported to a drying zone at 70° C. for 10 seconds and dried to prepare a cellulose acylate film which had been subjected to an alkali saponification treatment.

Alkaline solution

| | | |
|---|---|---|
| Potassium hydroxide | 4.7 | parts by mass |
| Water | 15.8 | parts by mass |
| Isopropanol | 63.7 | parts by mass |
| Surfactant: C₁₄H₂₉O(CH₂CH₂O)₂₀H | 1.0 | parts by mass |
| Propylene glycol | 14.8 | parts by mass |

### [Formation of Alignment Film]

An alignment film coating liquid having the following composition was continuously applied onto the surface of the cellulose acylate film that had been subjected to the alkali saponification treatment with a #14 wire bar. The film was dried with hot air at 60° C. for 60 seconds and further dried with hot air at 100° C. for 120 seconds to form an alignment film.

Alignment film coating liquid

| | | |
|---|---|---|
| Polyvinyl alcohol given below | 10 | parts by mass |
| Water | 371 | parts by mass |
| Methanol | 119 | parts by mass |
| Glutaraldehyde (crosslinking agent) | 0.5 | parts by mass |
| Citric acid ester (manufactured by Sankyo Chemical Co., Ltd.) | 0.175 | parts by mass |

Polyvinyl alcohol

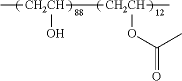

The above prepared alignment film was continuously subjected to a rubbing treatment. At this time, the longitudinal direction and the transport direction of the elongated film were parallel to each other, and the angle formed by the longitudinal direction (transport direction) of the film and the rotation axis of the rubbing roller was 90°.

The composition 2 described in Example 1 was applied onto the rubbing-treated alignment film using a geeser coating machine, and heated with hot air at 80° C. for 60 seconds. Subsequently, the obtained composition layer was irradiated with UV (500 mJ/cm²) at 80° C. to immobilize the alignment of the liquid crystal compound to form a positive A-plate.

The positive A-plate had a thickness of 0.53 μm and an Re(550) of 75 nm at a wavelength of 550 nm. Assuming that the width direction of the film is defined as 0° (the longitudinal direction of the film is defined as 90°), the in-plane slow axis direction (alignment axis angle of the liquid crystal compound) was 90°.

### (Preparation of Laminate 3)

A corona treatment was carried out on each of the surface of the positive A-plate of the film on the side opposite to the cellulose acylate film side and the surface of the first positive C-plate formed on the cellulose acylate film prepared in Example 1 on the side the opposite to the cellulose acylate film side. Thereafter, using an ultraviolet curable adhesive composition (1) having the following composition, the positive A-plate and the first positive C-plate were continuously bonded to each other such that the positive A plate and the first positive C plate face each other parallel to the longitudinal direction of the film. Next, the cellulose acylate film on the positive A-plate side was peeled off to expose the surface of the positive A-plate in contact with the cellulose acylate film.

The refractive index of the adhesive layer formed of an ultraviolet curable adhesive was 1.59, the refractive indices of the adjacent positive A-plate and first positive C-plate were 1.59 and 1.57, respectively, and the difference in refractive index between the positive A-plate and the adhesive layer and the difference in refractive index between the first positive C-plate and the adhesive layer were 0.00 and 0.02, respectively.

Ultraviolet curable adhesive composition (1)

| | |
|---|---|
| ARONIX UVX-6282 (manufactured by Toagosei | 20 parts by mass |
| Chemical Industry Co., Ltd.) | |
| LUMIPLUS LPK-2000 (manufactured by Mitsubishi | 80 parts by mass |
| Gas Chemical Company, Inc.) | |

### (Preparation of Circularly Polarizing Plate)

A circularly polarizing plate was prepared in the same manner as in Example 1, except that the laminate 3 was used instead of the laminate 1.

### Example 11

A circularly polarizing plate was prepared in the same manner as in Example 10, except that the following ultraviolet curable adhesive composition (2) was used instead of the ultraviolet curable adhesive composition (1) in Example 10. The refractive index of the adhesive layer was 1.51, the difference in refractive index between the adhesive layer and the adjacent positive A-plate was 0.08, and the difference in refractive index between the adhesive layer and the adjacent first positive C-plate was 0.06.

Ultraviolet curable adhesive composition (2)

| | |
|---|---|
| ARONIX UVX-6282 (manufactured by Toagosei | 80 parts by mass |
| Chemical Industry Co., Ltd.) | |
| LUMIPLUS LPK-2000 (manufactured by Mitsubishi | 20 parts by mass |
| Gas Chemical Company, Inc.) | |

### Comparative Example 2

A circularly polarizing plate was prepared in the same manner as in Example 10, except that the positive A-plate and the first positive C-plate were bonded to each other using a pressure sensitive adhesive OPTERIA NCF-D692 (thickness: 5 μm, manufactured by Lintec Corporation) instead of the ultraviolet curable adhesive. The refractive index of the pressure sensitive adhesive layer was 1.48, the difference in refractive index between the pressure sensitive adhesive layer and the adjacent positive A-plate was 0.11, and the difference in refractive index between the pressure sensitive adhesive layer and the adjacent first positive C-plate was 0.09.

### <Mounting of Circularly Polarizing Plate on Organic EL Display Panel and Evaluation of Display Performance>

### (Mounting of Circularly Polarizing Plate on Organic EL Display Device)

GALAXY S IV manufactured by Samsung Electronics Co., Ltd., equipped with an organic EL display panel, was disassembled, the circularly polarizing plate was peeled off, and each of the circularly polarizing plates of Examples 1 to 9 and Comparative Example 1 was bonded onto the organic EL display panel to prepare an organic EL display device.

### (Evaluation of Display Performance)

The prepared organic EL display device was observed at all azimuthal angles from an oblique direction (a direction tilted from the normal direction of the display device). That is, the reflectivity and the reflected tint of the organic EL display device were evaluated under bright light. Specifically, the reflected light in a case where a fluorescent lamp was projected from a polar angle of 45 degrees was observed in black display, where the reflected light of external light was most easily visible. More specifically, the reflected light in the viewing angle direction (a polar angle of 45 degrees, and an azimuthal angle of 0 to 165 degrees in increments of 15 degrees) was measured using a spectroradiometer SR-3 (manufactured by Topcon Corporation) and the measured results were evaluated according to the following standards using the organic EL display device of Comparative Example 1 as a reference. For all evaluations, an evaluation of A to C is preferable in terms of practical use.

### (Evaluation Standards for Reflectivity)

A: A case where the ratio of the maximum brightness of the reflected light in the organic EL display device to be evaluated to the maximum brightness of the reflected light in the organic EL display device of Comparative Example 1 is 40% or less
B: A case where the ratio of the maximum brightness of the reflected light in the organic EL display device to be evaluated to the maximum brightness of the reflected light in the organic EL display device of Comparative Example 1 is more than 40% and 60% or less
C: A case where the ratio of the maximum brightness of the reflected light in the organic EL display device to be evaluated to the maximum brightness of the reflected light in the organic EL display device of Comparative Example 1 is more than 60% and 80% or less
D: A case where the ratio of the maximum brightness of the reflected light in the organic EL display device to be evaluated to the maximum brightness of the reflected light in the organic EL display device of Comparative Example 1 is more than 80%

### (Evaluation Standards for Change in Tint)

The change in tint was defined as a magnitude Δa*b* (change in reflection tint) of change in tint a* and b* of the reflected light at all measurement angles using the following expression. The measuring device used was a spectroradiometer SR-3 (manufactured by Topcon Corporation). In the following expression, “maximum a*” and “maximum b*” mean a maximum value of a* and a maximum value of b* obtained in measurement, respectively. In addition, in the following expression, “minimum a*” and “minimum b*” mean a minimum value of a* and a minimum value of b* obtained in measurement, respectively.

$$Δ {a}^{*} {b}^{*} = \sqrt{{( maximum {a}^{*} - minimum {a}^{*} )}^{2} + {( maximum {b}^{*} - minimum {b}^{*} )}^{2}}$$

A: A case where the ratio of the change in the reflection tint of the reflected light in the organic EL display device to be evaluated to the change in the reflection tint of the reflected light in the organic EL display device of Comparative Example 1 is 40% or less
B: A case where the ratio of the change in the reflection tint of the reflected light in the organic EL display device to be evaluated to the change in the reflection tint of the reflected light in the organic EL display device of Comparative Example 1 is more than 40% and 60% or less
C: A case where the ratio of the change in the reflection tint of the reflected light in the organic EL display device to be evaluated to the change in the reflection tint of the reflected light in the organic EL display device of Comparative Example 1 is more than 60% and 80% or less
D: A case where the ratio of the change in the reflection tint of the reflected light in the organic EL display device to be evaluated to the change in the reflection tint of the reflected light in the organic EL display device of Comparative Example 1 is more than 80%

### <Results>

The configuration and evaluation results of the optical laminate of each of Examples and Comparative Examples are shown below.

In the table, “θ(P-A)” in the column of “Positive A-plate” represents an angle formed by the in-plane slow axis of the positive A-plate and the absorption axis of the polarizer.

In the table, “θ(Q-P)” in the column of “λ/4 plate” represents an angle formed by the in-plane slow axis of the λ/4 plate and the absorption axis of the polarizer. In addition, “θ(A-Q)” in the column of “λ/4 plate” represents an angle formed by the in-plane slow axis of the positive A-plate and the in-plane slow axis of the λ/4 plate.

In a case where the first positive C-plate and the positive A-plate are disposed adjacent to each other, the column of “Difference in refractive index” in the table represents a difference in refractive index between the first positive C-plate and the positive A-plate. In addition, in a case where another layer is disposed between the first positive C-plate and the positive A-plate, the column of “Difference in refractive index” represents a larger difference in refractive index of a difference in refractive index between the first positive C-plate and the other layer and a difference in refractive index between the positive A-plate and the other layer.

In the table, Rth(550), Re(550), and the like represent those measured by the above-mentioned method.

TABLE 1

| | | Examples | | | | | | |
|---|---|---|---|---|---|---|---|---|
| | | 1 | 2 | 3 | 4 | 5 | 6 | 7 |
| First | Re(550) [nm] | 0 | 0 | 0 | 0 | 0 | 0 | 0 |
| positive | Rth(550) [nm] | −55 | −70 | −55 | −55 | −70 | −40 | −55 |
| C-plate | Rth(450)/Rth(550) | 1.11 | 1.11 | 1.11 | 1.11 | 1.11 | 1.11 | 1.11 |
| | Rth(650)/Rth(550) | 0.95 | 0.95 | 0.95 | 0.95 | 0.95 | 0.95 | 0.95 |
| | Liquid crystal | Compo- | Compo- | Compo- | Compo- | Compo- | Compo- | Compo- |
| | composition | sition 1 | sition 1 | sition 1 | sition 1 | sition 1 | sition 1 | sition 1 |
| | Thickness [μm] | 0.49 | 0.62 | 0.49 | 0.49 | 0.62 | 0.36 | 0.49 |
| Positive | Re(550) [nm] | 75 | 75 | 90 | 75 | 90 | 75 | 60 |
| A-plate | Rth(550) [nm] | 37.5 | 37.5 | 45 | 37.5 | 45 | 37.5 | 30 |
| | Re(450)/Re(550) | 1.11 | 1.11 | 1.11 | 1.11 | 1.11 | 1.11 | 1.11 |
| | Re(650)/Re(550) | 0.95 | 0.95 | 0.95 | 0.95 | 0.95 | 0.95 | 0.95 |
| | θ(P-A) (°) | 0 | 0 | 0 | 0 | 0 | 0 | 0 |
| | Liquid crystal | Compo- | Compo- | Compo- | Compo- | Compo- | Compo- | Compo- |
| | composition | sition 2 | sition 2 | sition 2 | sition 2 | sition 2 | sition 2 | sition 2 |
| | Thickness [μm] | 0.53 | 0.53 | 0.64 | 0.53 | 0.64 | 0.53 | 0.42 |
| λ/4 plate | Re(550)[nm] | 141 | 141 | 141 | 141 | 141 | 141 | 141 |
| | Rth(550) [nm] | 70.5 | 70.5 | 70.5 | 70.5 | 70.5 | 70.5 | 70.5 |
| | Re(450)/Re(550) | 0.82 | 0.82 | 0.82 | 0.82 | 0.82 | 0.82 | 0.82 |
| | Re(650)/Re(550) | 1.04 | 1.04 | 1.04 | 1.04 | 1.04 | 1.04 | 1.04 |
| | θ(Q-P) (°) | 45 | 45 | 45 | 45 | 45 | 45 | 45 |
| | θ(A-Q) (°) | 45 | 45 | 45 | 45 | 45 | 45 | 45 |
| | Liquid crystal | Compo- | Compo- | Compo- | Compo- | Compo- | Compo- | Compo- |
| | composition | sition 3 | sition 3 | sition 3 | sition 3 | sition 3 | sition 3 | sition 3 |
| | Thickness [μm] | 2.8 | 2.8 | 2.8 | 2.8 | 2.8 | 2.8 | 2.8 |
| Second | Re(550) [nm] | 0 | 0 | 0 | 0 | 0 | 0 | 0 |
| positive | Rth(550) [nm] | −40 | −40 | −40 | −50 | −50 | −40 | −40 |
| C-plate | Rth(450)/Rth(550) | 1.11 | 1.11 | 1.11 | 1.11 | 1.11 | 1.11 | 1.11 |
| | Rth(650)/Rth(550) | 0.95 | 0.95 | 0.95 | 0.95 | 0.95 | 0.95 | 0.95 |
| | Liquid crystal | Compo- | Compo- | Compo- | Compo- | Compo- | Compo- | Compo- |
| | composition | sition 1 | sition 1 | sition 1 | sition 1 | sition 1 | sition 1 | sition 1 |
| | Thickness [μm] | 0.35 | 0.35 | 0.35 | 0.44 | 0.44 | 0.35 | 0.35 |
| Difference in refractive index | | 0.02 | 0.02 | 0.02 | 0.02 | 0.02 | 0.02 | 0.02 |
| Display | Reflectivity | A | A | B | B | A | B | B |
| performance | Change in tint | A | B | A | B | C | B | B |

| | | Examples | | | | Comparative Examples | |
|---|---|---|---|---|---|---|---|
| | | 8 | 9 | 10 | 11 | 1 | 2 |
| First | Re(550) [nm] | 0 | 0 | 0 | 0 | — | 0 |
| positive | Rth(550) [nm] | −55 | −40 | −55 | −55 | — | −55 |
| C-plate | Rth(450)/Rth(550) | 1.11 | 1.11 | 1.11 | 1.11 | — | 1.11 |
| | Rth(650)/Rth(550) | 0.95 | 0.95 | 0.95 | 0.95 | — | 0.95 |
| | Liquid crystal | Compo- | Compo- | Compo- | Compo- | — | Compo- |
| | composition | sition 1 | sition 1 | sition 1 | sition 1 | | sition 1 |
| | Thickness [μm] | 0.49 | 0.36 | 0.49 | 0.49 | — | 0.49 |
| Positive | Re(550) [nm] | 75 | 60 | 75 | 75 | — | 75 |
| A-plate | Rth(550) [nm] | 37.5 | 30 | 37.5 | 37.5 | — | 37.5 |
| | Re(450)/Re(550) | 1.11 | 1.11 | 1.11 | 1.11 | — | 1.11 |
| | Re(650)/Re(550) | 0.95 | 0.95 | 0.95 | 0.95 | — | 0.95 |
| | θ(P-A) (°) | 0 | 0 | 0 | 0 | — | 0 |
| | Liquid crystal | Compo- | Compo- | Compo- | Compo- | — | Compo- |
| | composition | sition 2 | sition 2 | sition 2 | sition 2 | | sition 2 |
| | Thickness [μm] | 0.53 | 0.42 | 0.53 | 0.53 | — | 0.53 |
| λ/4 plate | Re(550)[nm] | 141 | 141 | 141 | 141 | 141 | 141 |
| | Rth(550) [nm] | 70.5 | 70.5 | 70.5 | 70.5 | 70.5 | 70.5 |
| | Re(450)/Re(550) | 0.82 | 0.82 | 0.82 | 0.82 | 0.82 | 0.82 |
| | Re(650)/Re(550) | 1.04 | 1.04 | 1.04 | 1.04 | 1.04 | 1.04 |
| | θ(Q-P) (°) | 45 | 45 | 45 | 45 | 45 | 45 |
| | θ(A-Q) (°) | 45 | 45 | 45 | 45 | 45 | 45 |
| | Liquid crystal | Compo- | Compo- | Compo- | Compo- | Compo- | Compo- |
| | composition | sition 3 | sition 3 | sition 3 | sition 3 | sition 3 | sition 3 |
| | Thickness [μm] | 2.8 | 2.8 | 2.8 | 2.8 | 2.8 | 2.8 |
| Second | Re(550) [nm] | 0 | 0 | 0 | 0 | 0 | 0 |
| positive | Rth(550) [nm] | −30 | −30 | −40 | −40 | −70 | −40 |
| C-plate | Rth(450)/Rth(550) | 1.11 | 1.11 | 1.11 | 1.11 | 1.11 | 1.11 |
| | Rth(650)/Rth(550) | 0.95 | 0.95 | 0.95 | 0.95 | 0.95 | 0.95 |
| | Liquid crystal | Compo- | Compo- | Compo- | Compo- | Compo- | Compo- |
| | composition | sition 1 | sition 1 | sition 1 | sition 1 | sition 1 | sition 1 |
| | Thickness [μm] | 0.26 | 0.26 | 0.35 | 0.35 | 0.61 | 0.35 |
| Difference in refractive index | | 0.02 | 0.02 | 0.02 | 0.08 | 0.02 | 0.11 |
| Display | Reflectivity | C | C | A | B | D | D |
| performance | Change in tint | C | C | A | B | D | D |

As shown in Table 1, the desired effect was obtained in the organic EL display device according to the embodiment of the present invention.

In particular, from the comparison of Examples 1, 2, and 6, it was confirmed that the effect of the present invention is more excellent in a case where the Rth(550) of the first positive C-plate is −65 to −45 nm.

In addition, from the comparison of Examples 1, 3, and 7, it was confirmed that the effect of the present invention is more excellent in a case where the Re(550) of the positive A-plate is 65 to 95 nm.

In addition, from the comparison of Examples 1, 4, and 8, it was confirmed that the effect of the present invention is more excellent in a case where the Rth(550) of the second positive C-plate is −45 to −35 nm.

On the other hand, a desired effect could not be obtained in Comparative Example 1 in which the first positive C-plate and the positive A-plate were not provided. In addition, a desired effect could not be obtained in Comparative Example 2 in which, in a case where the first positive C-plate and the positive A-plate are disposed adjacent to each other, the difference in refractive index between the first positive C-plate and the positive A-plate is not 0.08 or less and in a case where another layer is disposed between the first positive C-plate and the positive A-plate, a larger difference in refractive index of a difference in refractive index between the first positive C-plate and the other layer and a difference in refractive index between the positive A-plate and the other layer is not 0.08 or less.

### Example 12

An optical laminate 1 in which a second positive C-plate, a λ/4 plate, a positive A-plate, and a first positive C-plate were laminated in this order on a cellulose acylate film was obtained in the same manner as in Example 1.

Next, a polarizer formed of a dichroic organic coloring agent and a polymerizable liquid crystal compound was prepared as a polarizing film by the following procedure.

A coating liquid PA1 for forming an alignment layer, which will be described later, was continuously applied onto a cellulose triacetate film TJ40 (manufactured by FUJIFILM Corporation, thickness: 40 μm) with a wire bar. The support on which the coating film was formed was dried with hot air at 140° C. for 120 seconds, and then the coating film was irradiated with polarized ultraviolet rays (10 mJ/cm², using an ultra-high pressure mercury lamp) to form a photoalignment layer PA1, thereby obtaining a TAC film with a photoalignment layer PA1.

The film thickness of the photoalignment layer PA1 was 0.3 μm.

Coating liquid PA1 for forming alignment layer

| | | |
|---|---|---|
| Polymer PA-1 given below | 100.0 | parts by mass |
| Acid generator PAG-1 given below | 5.0 | parts by mass |
| Acid generator CPI-110TF given below | 0.005 | parts by mass |
| Xylene | 1220.00 | parts by mass |
| Methyl isobutyl ketone | 122.00 | parts by mass |

Polymer PA-1 (weight-average molecular weight: 35,000) 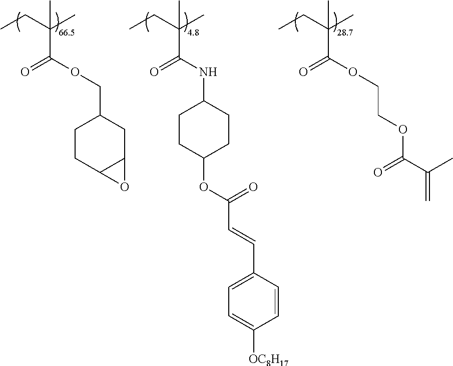
Acid generator PAG-1 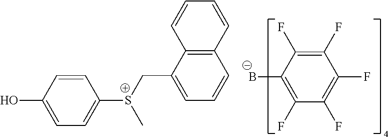
Acid generator CPI-110F

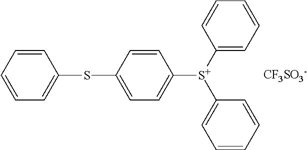

The following composition P2 for forming a light-absorbing anisotropic layer was continuously applied onto the obtained photoalignment layer PA1 with a wire bar to form a coating film P2.

Next, the coating film P2 was heated at 140° C. for 30 seconds, and then the coating film P2 was cooled to room temperature (23° C.).

Next, the obtained coating film P2 was heated at 90° C. for 60 seconds and cooled again to room temperature.

Then, a light-absorbing anisotropic layer P2 was prepared on the photoalignment layer PA1 by irradiation with a light emitting diode (LED) lamp (central wavelength: 365 nm) for 2 seconds under an irradiation condition of an illuminance of 200 mW/cm². The molar content of radically polymerizable groups is 1.17 mmol/g.

The film thickness of the light-absorbing anisotropic layer P2 was 1.0 μm.

Composition P2 for forming light-absorbing anisotropic layer

| | | |
|---|---|---|
| Dichroic coloring agent D-4 given below | 0.25 | parts by mass |
| Dichroic coloring agent D-5 given below | 0.36 | parts by mass |
| Dichroic coloring agent D-6 given below | 0.59 | parts by mass |
| Polymer liquid crystal compound P-1 given below | 2.21 | parts by mass |
| Low-molecular-weight liquid crystalline compound M-1 given below | 1.36 | parts by mass |
| Polymerization initiator | | |
| IRGACURE OXE-02 (manufactured by BASF SE) | 0.150 | parts by mass |
| Surfactant F-1 given below | 0.026 | parts by mass |
| Cyclopentanone | 46.00 | parts by mass |
| Tetrahydrofuran | 46.00 | parts by mass |
| Benzyl alcohol | 3.00 | parts by mass |

Dichroic coloring agent D-4 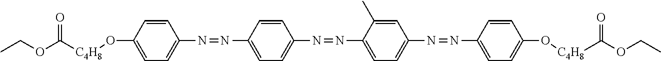
Dichroic coloring agent D-5 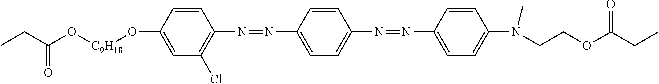
Dichroic coloring agent D-6 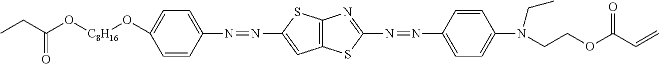
Polymer liquid crystal compound P-1 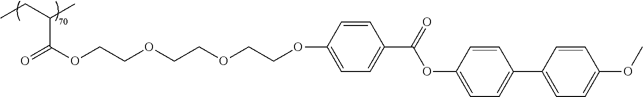 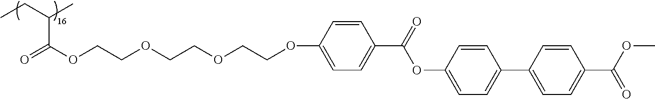 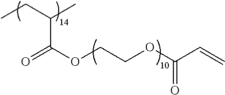
Low-molecular-weight liquid crystalline compound M-1 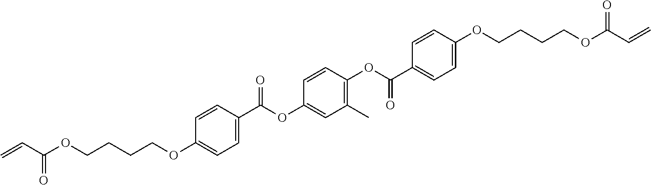 [SMILES: C=CC(=O)OCCCCOc1ccc(C(=O)Oc2ccc(OC(=O)c3ccc(OCCCCOC(=O)C=C)cc3)c(C)c2)cc1]
Surfactant F-1

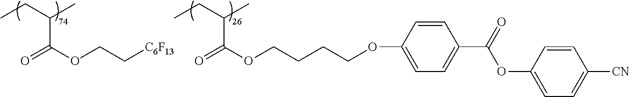

The following composition K1 for forming a cured layer was continuously applied onto the obtained light-absorbing anisotropic layer P2 with a wire bar to form a coating film.

Next, the coating film was dried at room temperature, and then irradiated with a high-pressure mercury lamp for 15 seconds under an irradiation condition of an illuminance of 28 mW/cm² to prepare a cured layer K1 on the light-absorbing anisotropic layer P2.

The film thickness of the cured layer K1 was 0.05 μm.

Composition K1 for forming cured layer

| | | |
|---|---|---|
| Rod-like liquid crystal compound (A) given above | 2.61 | parts by mass |
| Modified trimethylolpropane triacrylate given below | 0.11 | parts by mass |
| Photopolymerization initiator I-1 given below | 0.05 | parts by mass |
| Surfactant F-3 given below | 0.21 | parts by mass |
| Methyl isobutyl ketone | 297 | parts by mass |

Modified trimethylolpropane triacrylate 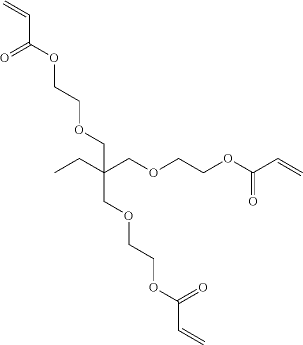 [SMILES: C=CC(=O)OCCOCC(CC)(COCCOC(=O)C=C)COCCOC(=O)C=C]
Photopolymerization initiator I-1 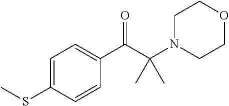 [SMILES: CSc1ccc(C(=O)C(C)(C)N2CCOCC2)cc1]
Surfactant F-3

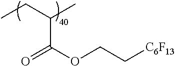

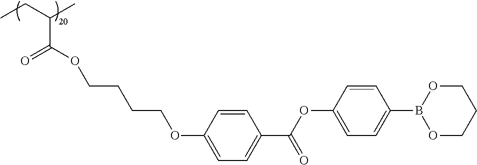

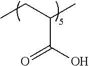

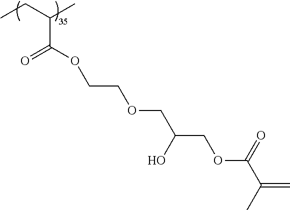

The following composition B2 for forming an oxygen barrier layer was continuously applied onto the cured layer K1 with a wire bar. This was followed by drying with hot air at 100° C. for 2 minutes to form an oxygen barrier layer B2 having a thickness of 1.0 μm on the cured layer K1 to prepare a polarizing film including the light-absorbing anisotropic layer P2.

The luminosity corrected single transmittance of the polarizing film was 44%.

Composition B2 for forming oxygen barrier layer

| | | |
|---|---|---|
| Modified polyvinyl alcohol given below | 3.80 | parts by mass |
| Initiator IRGACURE 2959 | 0.20 | parts by mass |
| Water | 70 | parts by mass |
| Methanol | 30 | parts by mass |

Modified polyvinyl alcohol

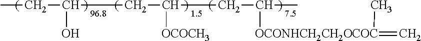

The oxygen barrier layer B2 side of the polarizing film and the polarizer protective film were bonded to each other using a pressure-sensitive adhesive sheet. After that, only TJ40 of the polarizing film was peeled off, and the peeled surface and the surface of the first positive C-plate of the optical laminate 1 were continuously bonded to each other using an ultraviolet curable adhesive. Subsequently, the cellulose acylate film on the second positive C-plate side was peeled off to expose the surface of the second positive C-plate in contact with the cellulose acylate film. In this manner, a circularly polarizing plate 2 was prepared.

### Example 13

The following pressure sensitive adhesive A was used instead of the ultraviolet curable adhesive used in Example 1 to prepare a circularly polarizing plate 3.

The pressure sensitive adhesive A had a refractive index controlled to 1.54, and formed a pressure sensitive adhesive layer having a thickness of 15 μm. The difference in refractive index between the polarizer adjacent to the pressure sensitive adhesive layer and the pressure sensitive adhesive A and the difference in refractive index between the second positive C-plate and the pressure sensitive adhesive A were both within 0.08.

### Example 14

The following pressure sensitive adhesive B was used instead of the ultraviolet curable adhesive used in Example 1 to prepare a circularly polarizing plate 4.

The pressure sensitive adhesive B contained UV-2 described in WO2021/006097A as an ultraviolet absorber, had a refractive index controlled to 1.54, and formed a pressure sensitive adhesive layer having a thickness of 25 μm. The difference in refractive index between the polarizer adjacent to the pressure sensitive adhesive layer and the pressure sensitive adhesive B and the difference in refractive index between the second positive C-plate and the pressure sensitive adhesive B were both within 0.08. In addition, the light transmittance of the circularly polarizing plate 4 at a wavelength of 380 nm was 1% or less. The light transmittance was measured with a spectrophotometer UV-3150 (manufactured by Shimadzu Corporation).

### (Evaluation of Display Performance)

In a case where the polarizing plate of each of Examples 12 to 14 was mounted on an organic EL display device in the same manner as in Example 1, the display performance equivalent to that of Example 1 was confirmed.

### EXPLANATION OF REFERENCES

10: optical laminate
12: first positive C-plate
14: positive A-plate
16: λ/4 plate
18: second positive C-plate
20: circularly polarizing plate
22: polarizer
24: organic EL display device
26: organic EL display panel

What is claimed is:

1. A circularly polarizing plate comprising:
a polarizer; and
an optical laminate,
wherein the optical laminate has a first positive C-plate, a positive A-plate, and a λ/4 plate from a side of the polarizer,
an in-plane slow axis of the positive A-plate and an absorption axis of the polarizer are parallel to each other,
an angle formed by the in-plane slow axis of the positive A-plate and an in-plane slow axis of the λ/4 plate is 45°±10°,
in a case where the first positive C-plate and the positive A-plate are disposed adjacent to each other, a difference in refractive index between the first positive C-plate and the positive A-plate is 0.08 or less, and
in a case where another layer is disposed between the first positive C-plate and the positive A-plate, a larger difference in refractive index of a difference in refractive index between the first positive C-plate and the other layer and a difference in refractive index between the positive A-plate and the other layer is 0.08 or less.

2. The circularly polarizing plate according to claim 1,
wherein a thickness direction retardation of the first positive C-plate at a wavelength of 550 nm is −65 to −45 nm.

3. The circularly polarizing plate according to claim 1,
wherein an in-plane retardation of the positive A-plate at a wavelength of 550 nm is 65 to 85 nm.

4. The circularly polarizing plate according to claim 1, further comprising:
a second positive C-plate on a side of the λ/4 plate opposite to the side of the polarizer,
wherein a thickness direction retardation of the second positive C-plate at a wavelength of 550 nm is −45 to −35 nm.

5. The circularly polarizing plate according to claim 1,
wherein the λ/4 plate exhibits reverse wavelength dispersibility.

6. The circularly polarizing plate according to claim 1,
wherein the first positive C-plate and the positive A-plate are disposed adjacent to each other.

7. The circularly polarizing plate according to claim 4,
wherein the λ/4 plate and the second positive C-plate are disposed adjacent to each other.

8. The circularly polarizing plate according to claim 1,
wherein any of the first positive C-plate, the positive A-plate, and the λ/4 plate is a layer formed of a liquid crystal compound.

9. The circularly polarizing plate according to claim 1,
wherein the polarizer is a polarizer formed of a composition containing a polymerizable liquid crystal compound.

10. The circularly polarizing plate according to claim 1, further comprising;
an adhesion layer in at least any of a space between the polarizer and the first positive C-plate, a space between the first positive C-plate and the positive A-plate, or a space between the positive A-plate and the λ/4 plate.

11. The circularly polarizing plate according to claim 10,
wherein a difference in refractive index between the adhesion layer and an adjacent layer is 0.08 or less.

12. An optical laminate comprising, in the following order:
a first positive C-plate;
a positive A-plate; and
a λ/4 plate,
wherein an angle formed by an in-plane slow axis of the positive A-plate and an in-plane slow axis of the λ/4 plate is 45°±10°,
in a case where the first positive C-plate and the positive A-plate are disposed adjacent to each other, a difference in refractive index between the first positive C-plate and the positive A-plate is 0.08 or less, and
in a case where another layer is disposed between the first positive C-plate and the positive A-plate, a larger difference in refractive index of a difference in refractive index between the first positive C-plate and the other layer and a difference in refractive index between the positive A-plate and the other layer is 0.08 or less.

13. The optical laminate according to claim 12,
wherein a thickness direction retardation of the first positive C-plate at a wavelength of 550 nm is −65 to −45 nm.

14. The optical laminate according to claim 12,
wherein an in-plane retardation of the positive A-plate at a wavelength of 550 nm is 65 to 85 nm.

15. The optical laminate according to claim 12, further comprising:
a second positive C-plate on a side of the λ/4 plate opposite to a side of the positive A-plate,
wherein a thickness direction retardation of the second positive C-plate at a wavelength of 550 nm is −45 to −35 nm.

16. The optical laminate according to claim 12,
wherein the λ/4 plate exhibits reverse wavelength dispersibility.

17. The optical laminate according to claim 12,
wherein the first positive C-plate and the positive A-plate are disposed adjacent to each other.

18. The optical laminate according to claim 15,
wherein the λ/4 plate and the second positive C-plate are disposed adjacent to each other.

19. The optical laminate according to claim 12,
wherein any of the first positive C-plate, the positive A-plate, and the λ/4 plate is a layer formed of a liquid crystal compound.

20. The optical laminate according to claim 12, further comprising:
an adhesion layer in at least any of a space between the first positive C-plate and the positive A-plate or a space between the positive A-plate and the λ/4 plate.

21. The optical laminate according to claim 20,
wherein a difference in refractive index between the adhesion layer and an adjacent layer is 0.08 or less.

22. An organic electroluminescent display device comprising:
the circularly polarizing plate according to claim 1.

23. A display device comprising:
the circularly polarizing plate according to claim 1,
wherein the circularly polarizing plate or the optical laminate is disposed along a curved surface of the display device.
